(19) United States
(12) Patent Application Publication
(10) Pub. No.: US 2026/0354159 A1
(43) Pub. Date: Nov. 5, 2026

(54) SEMICONDUCTOR DEVICES HAVING DOUBLE LAYERED BIT LINES

(71) Applicant: Samsung Electronics Co., Ltd., Suwon-si (KR)

(72) Inventor: Joonam KIM, Suwon-si (KR)

(21) Appl. No.: 19/645,845

(22) Filed: Apr. 13, 2026

(30) Foreign Application Priority Data
May 2, 2025 (KR) 10-2025-0058542

(51) Int. Cl. H10W 20/43; H10W 20/42; H10B 43/27

(52) U.S. Cl. CPC H10W 20/43; H10W 20/421; H10B 43/27

(57) ABSTRACT

A semiconductor device includes a substrate including a first region having second regions and third regions, a peripheral circuit pattern on the substrate, a gate electrode structure on each of the second regions of the substrate, memory channel structures each extending through the gate electrode structure, a first bit line and a second bit line on the gate electrode structures, a third bit line on the first bit line, and through-vias on the third regions of the substrate. A third primary region of the third regions is closer to a first edge of the first region than a third secondary region of the third regions in the first direction. The first bit line is electrically connected to the peripheral circuit pattern through a first through-via, and the second bit line is electrically connected to the peripheral circuit pattern through a second through-via.

### CROSS-REFERENCE TO RELATED APPLICATION

This application claims priority under 35 U.S.C. § 119 to Korean Patent Application No. 10-2025-0058542, filed on May 02, 2025 in the Korean Intellectual Property Office (KIPO), the disclosure of which is incorporated by reference herein in its entirety.

### TECHNICAL FIELD

Example embodiments of the inventive concept relate to a semiconductor device. More particularly, example embodiments of the inventive concept relate to a vertical memory device.

### DISCUSSION OF RELATED ART

In an electronic system including data storage, a semiconductor device capable of storing a large amount of data is desirable. Accordingly, solutions capable of increasing data storage capacity of semiconductor devices are being studied. For example, as one method for increasing the data storage capacity of semiconductor devices, semiconductor devices including memory cells arranged in three dimensions instead of memory cells arranged in two dimensions are being proposed.

In semiconductor devices, processes for efficiently forming contact plugs for transmitting electrical signal to memory cells are desirable.

### SUMMARY

Example embodiments of the inventive concept provide a semiconductor device having enhanced electrical characteristics.

According to example embodiments of the inventive concept, there is provided a semiconductor device. The semiconductor device may include a substrate including a first region having second regions and third regions alternately and repeatedly arranged in a first direction, a peripheral circuit pattern on the substrate, a gate electrode structure on each of the second regions of the substrate, memory channel structures each extending through the gate electrode structure, a first bit line and a second bit line on the gate electrode structures in the first region of the substrate, each of the first bit line and the second bit line extending in the first direction, and the first bit line and the second bit line being spaced apart from each other in a second direction crossing the first direction, a third bit line extending in the first direction on the first bit line, and through-vias on the third regions of the substrate. The third regions may include a third primary region and a third secondary region. The third primary region may be closer to a first edge of the first region than the third secondary region in the first direction. The first bit line may be electrically connected to the peripheral circuit pattern through a first through-via disposed on the third primary region among the through-vias, and the second bit line may be electrically connected to the peripheral circuit pattern through a second through-via disposed on the third secondary region of the substrate among the through-vias.

According to example embodiments of the inventive concept, there is provided a semiconductor device. The semiconductor device may include a peripheral circuit pattern on a substrate including a first region, bonding pattern structures on the peripheral circuit pattern, a first bit line structure on the bonding pattern structures, the first bit line structure including a first bit line extending a first direction parallel to an upper surface of the substrate, and a second bit line contacting an upper surface of the first bit line, the second bit line extending in the first direction on the upper surface of the first bit line, a third bit line extending in the first direction, the third bit line spaced apart from the second bit line in a second direction parallel to the upper surface of the substrate and crossing the first direction, a gate electrode structure on the first bit line structure and the third bit line, and memory channel structure extend through the gate electrode structure on the first region of the substrate. The bonding pattern structures may include a first bonding pattern structure closer to a first edge of the first region than a second bonding pattern structure in the first direction. The first bit line structure may be electrically connected to the peripheral circuit pattern through the first bonding pattern structure, and the third bit line may be electrically connected to the peripheral circuit pattern through the second bonding pattern structure.

According to example embodiments of the inventive concept, there is provided a semiconductor device. The semiconductor device may include a substrate including a first region having second regions and third regions that are alternately and repeatedly arranged in a first direction, a peripheral circuit pattern on the substrate; and a first bonding pattern structure, a first cell structure, a second bonding pattern structure, and a second cell structure sequentially stacked in a vertical direction on the peripheral circuit pattern. The first cell structure may include a first bit line group on the first bonding pattern structure, a first gate electrode structure on the first bit line group on the second regions of the substrate, first memory channel structures each extending through the first gate electrode structure, and through-vias on the third regions of the substrate. The second cell structure may include a second bit line group on the second bonding pattern structures, a second gate electrode structure on the second bit line group in the second regions of the substrate, and second memory channel structures each extending through the second gate electrode structure. The second bit line group may include a first bit line structure on the second bonding pattern structure, the first bit line structure including a first bit line extending in the first direction and a second bit line extending on an upper surface of the first bit line in the first direction and a third bit line extending in the first direction, the third bit line being spaced apart from the second bit line in a second direction parallel to the upper surface of the substrate and crossing the first direction. The third regions may include a third primary region and a third secondary region. The third primary region may be closer to a first edge of the first region than the third secondary region in the first direction. The first bit line structure may be electrically connected to the peripheral circuit pattern through a first through-via disposed on the third primary region of the substrate among the through-vias, and the third bit line may be electrically connected to the peripheral circuit pattern through a second through-via disposed on the third secondary region of the substrate among the through-vias.

The semiconductor device in accordance with example embodiments may introduce a double-layered structure in which a second layer of a bit line is additionally disposed on a bit line connected to a page buffer through a through-via of an edge, thereby increasing an effective cross-sectional area and reducing resistance. Accordingly, RC delay may be reduced, a pre-charge current may propagate quickly, and consequently, an overall memory operation speed may be enhanced.

### BRIEF DESCRIPTION OF THE DRAWINGS

FIG. 1 is a plan view of a semiconductor device in accordance with example embodiments of the present disclosure.

FIG. 2 is a plan view showing a layout of elements in a region X of FIG. 1 in accordance with example embodiments of the present disclosure.

FIG. 3 is an enlarged plan view of a portion of FIG. 2.

FIG. 4 shows cross-sectional views illustrating a semiconductor device taken along a line A-A’ and a line B-B’ of FIG. 3 in accordance with example embodiments.

FIG. 5 is a cross-sectional view of a portion of the semiconductor device taken along a line C-C’ of FIG. 3 in accordance with example embodiments.

FIG. 6 is a plan view showing a layout of elements of a semiconductor device in accordance with example embodiments.

FIG. 7 is a cross-sectional view illustrating a semiconductor device in accordance with example embodiments.

FIG. 8 is a layout illustrating a semiconductor device in accordance with example embodiments.

FIG. 9 is a cross-sectional view illustrating a semiconductor device in accordance with example embodiments.

FIGS. 10 and 11 are cross-sectional views illustrating a semiconductor device in accordance with example embodiments.

FIGS. 12 and 13 are a layout and a cross-sectional view, respectively, illustrating a semiconductor device in accordance with example embodiments.

FIG. 14 is a layout illustrating a semiconductor device in accordance with example embodiments.

FIG. 15 is a layout illustrating a semiconductor device in accordance with example embodiments.

FIG. 16 is a cross-sectional view illustrating a semiconductor device in accordance with example embodiments.

FIG. 17 is a cross-sectional view illustrating a semiconductor device in accordance with example embodiments.

FIGS. 18, 21, 23, 25, and 27 are plan views and FIGS. 19, 20, 22, 24, 26, 28, and 29 are cross-sectional views illustrating a method of manufacturing the semiconductor device of FIGS. 1-5 in accordance with example embodiments.

FIGS. 30-32 are cross-sectional views illustrating a method of manufacturing the semiconductor device of FIG. 12 and 13 in accordance with example embodiments.

FIG. 33 is a block diagram illustrating a semiconductor device in accordance with example embodiments.

### DETAILED DESCRIPTION OF THE EMBODIMENTS

The above and other aspects and features of the semiconductor devices and the methods of manufacturing the same in accordance with example embodiments will become readily understood from detailed descriptions that follow, with reference to the accompanying drawings. It will be understood that, although ordinal numbers such as “first,” “second,” “third,” etc. may be used herein to describe various materials, layers, regions, pads, electrodes, patterns, structure and/or processes, these various materials, layers, regions, pads, electrodes, patterns, structure and/or processes should not be limited by these terms. The ordinal numbers are used merely to distinguish one material, layer, region, pad, electrode, pattern, structure or process from another material, layer, region, pad, electrode, pattern, structure or process. Thus, “first”, “second,” “third,” etc. may be used selectively or interchangeably for each material, layer, region, electrode, pad, pattern, structure or process respectively.

A direction perpendicular to an upper surface of a substrate may be referred to as a first direction D1, and two horizontal directions that are parallel to the upper surface of the substrate, which intersect each other, may be referred to as second and third directions D2 and D3, respectively. In example embodiments, the second and third directions D2 and D3 may be perpendicular to each other. The first direction D1 may be a vertical direction.

The first to third directions D1, D2, and D3 may include directions not only directions indicated by arrows in the drawings but also directions opposite thereto.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Spatially relative terms, such as “beneath,” “below,” “lower,” “above,” “upper,” “top,” “bottom,” “front,” “rear,” “horizontal,” “vertical,” and the like, may be used herein for ease of description to describe positional relationships, such as illustrated in the figures, for example. It will be understood that the spatially relative terms encompass different orientations of the device in addition to the orientation depicted in the figures.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred).

As used herein, singular forms 'a,' 'an,' and 'the' are intended to include plural forms as well as the singular forms, unless the context clearly indicates otherwise.

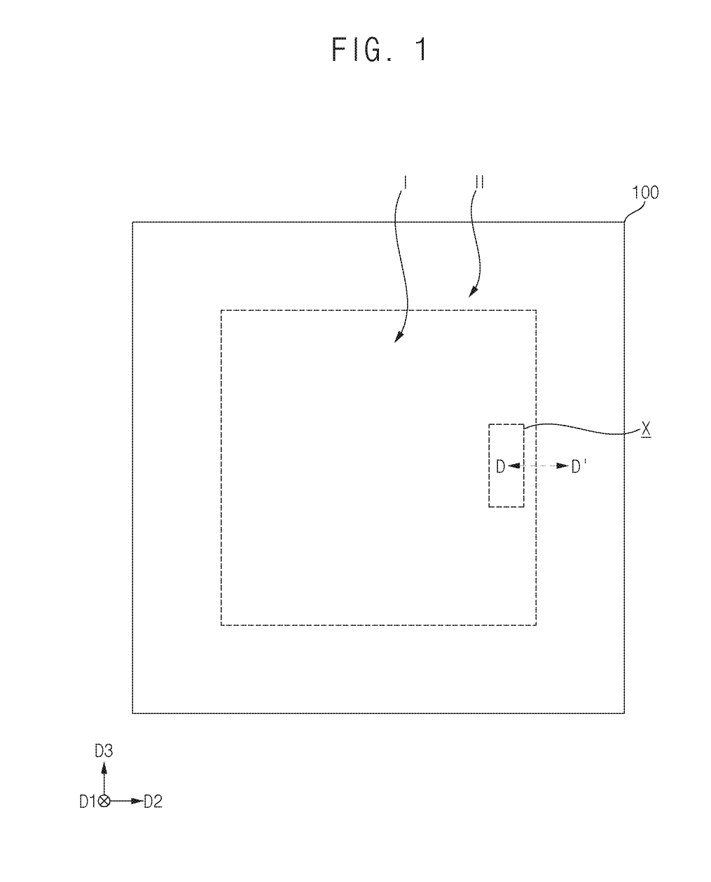

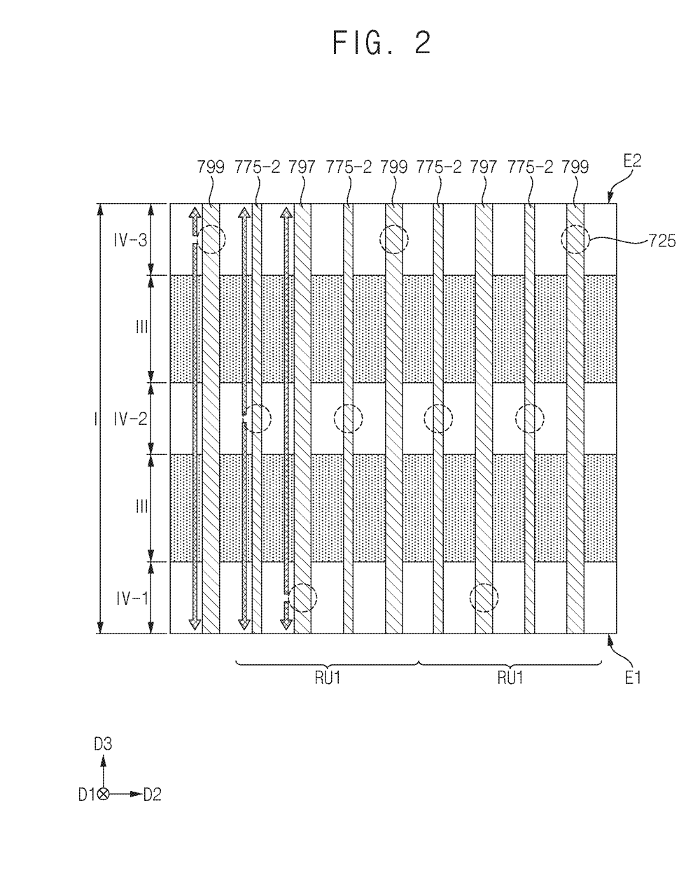

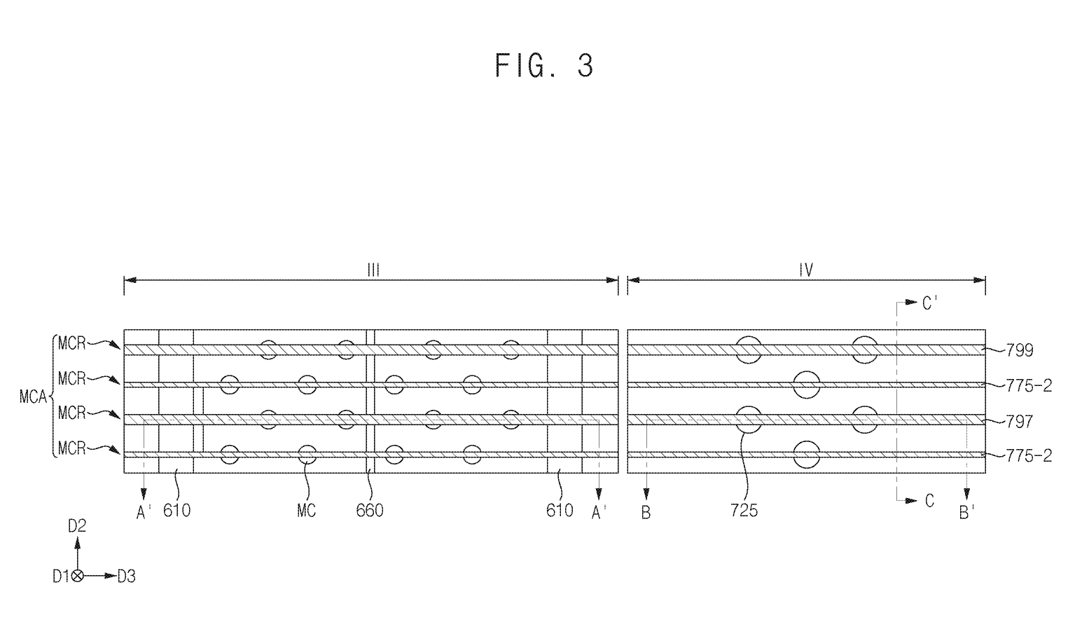

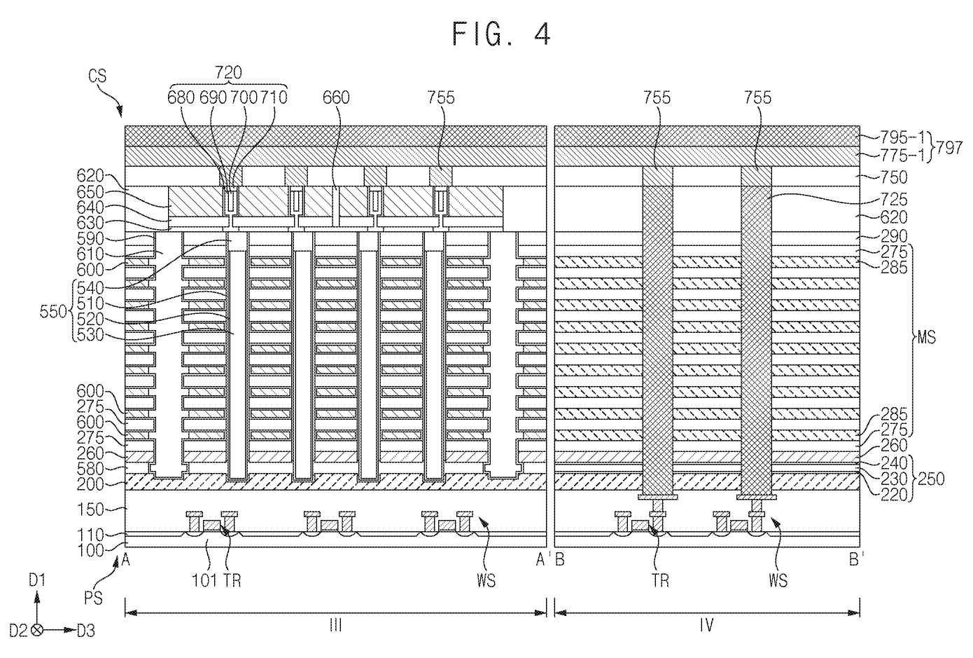

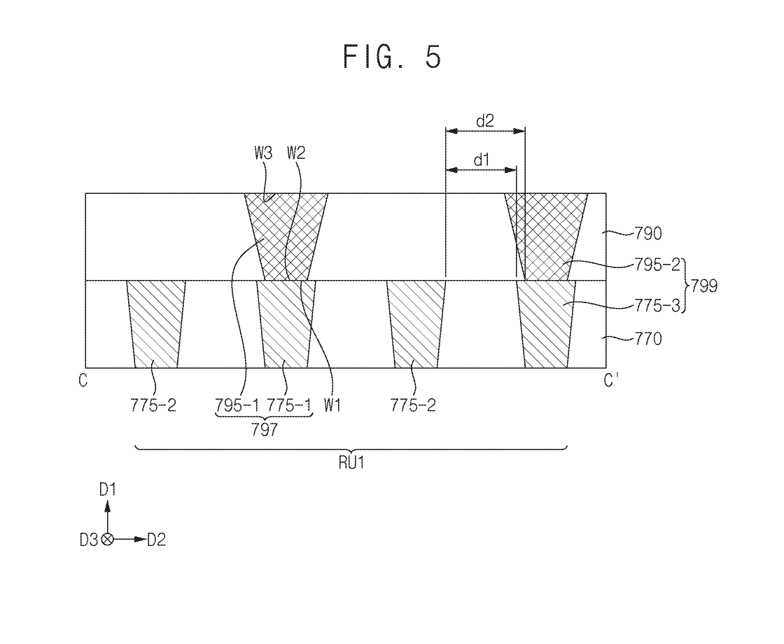

FIGS. 1-5 illustrate a semiconductor device in accordance with example embodiments. Particularly, FIG. 1 is the plan view. FIG. 2 is a planar layout (or a plan view) of bit lines and some other elements. FIG. 3 is an enlarged planar layout (or a plan view) of a portion of FIG. 2. FIG. 4 includes cross-sectional views taken along a line A-A’ and a line B-B’, respectively, of FIG. 3. FIG. 5 is a cross-sectional view of a portion of the semiconductor device taken along a line C-C’ of FIG. 3. FIGS. 2-5 are drawings of a region X of FIG. 1.

Referring to FIGS. 1-5, the semiconductor device may have a COP (Cell Over Periphery) structure. For example, a cell structure CS including memory cells may be disposed on a peripheral circuit structure PS.

The peripheral circuit structure PS may include a peripheral circuit pattern disposed on a first substrate 100 and a first insulating interlayer 150.

The cell structure CS may include a first common source plate (CSP) 200 disposed on the peripheral circuit structure PS, a gate electrode structure, a memory channel structure MC, a mold structure MS, a through-via 725, a first via 755, a first bit line structure 797 including a 1-1 bit line (a bit line which may be called a first primary bit line) and a 2-1 bit line (a bit line which may be called a second primary bit line), a 1-2 bit line (a bit line which may be called a first secondary bit line) 775-2, a third bit line structure 799 including a 1-3 bit line (a bit line which may be called first tertiary bit line) and a 2-2 bit line (a bit line which may be called a second secondary bit line), and first, second, third, fourth, fifth, sixth, and seventh insulating interlayers 150, 290, 620, 630, 750, 770, and 790. For example, the 1-1, 1-2, and 1-3 bit lines may be first bit lines 775, and the 2-1 and 2-2 bit lines may be second bit lines 795.

In addition, the cell structure CS may include a sacrificial layer structure 250, a support layer 260, a support pattern 265, a channel connection pattern 580, a first insulating pattern 275, first and second separation patterns 610 and 660, and a second blocking pattern 590.

The first substrate 100 may include a semiconductor material such as silicon, germanium, or silicon-germanium, or a group III-V compound such as GaP, GaAs, GaSb, etc. In an example embodiment, the first substrate 100 may be a silicon-on-insulator (SOI) substrate or a germanium-on-insulator (GOI) substrate.

The first substrate 100 may include a first region I and a second region II surrounding the first region I. In example embodiments, the first region I of the first substrate 100 may be a cell array region in which memory cells are disposed, and the second region II of the first substrate 100 may be an extension region in which contact plugs for transmitting signals to the memory cells are disposed. The first and second regions I and II of the first substrate 100 may collectively form a cell region. FIG. 1 shows that the second region II entirely surrounds the first region I. For example, the second region II may form a closed loop along an edge of the first region I. However, the embodiments are not limited thereto. For example, the second region II may be disposed only on one side of the first region I in the second direction D2 in certain embodiments.

The first region I of the first substrate 100 may include a third region III and a fourth region IV. The third region III may be an active memory region on which the memory channel structure MC is disposed, and the fourth region IV may be a through-via region on which the through-via 725 for providing electrical connection between the peripheral circuit pattern and bit lines, which are disposed at different vertical levels. In example embodiments, a plurality of third regions III and a plurality of fourth regions IV may be alternately and repeatedly arranged in the third direction D3. For example, each of the third regions III may be disposed between a corresponding pair of the fourth regions IV adjacent to each other in the third direction D3.

In example embodiments, a pair of the fourth regions IV disposed adjacent to opposite ends in the third direction D3 of the first region I, that is, first and second edge portions (or edges) E1 and E2 of the first region I may be referred to as a 4-1 region (e.g., a fourth primary region) IV-1 and a 4-3 region (e.g., a fourth tertiary region) IV-3, respectively, and one of the fourth regions IV disposed between the 4-1 region IV-1 and the 4-3 region IV-3 may be referred to as a 4-2 region (e.g., a fourth secondary region) IV-2.

In example embodiments, a difference between two distances measured from the 4-2 region IV-2 to the first and second edge portions (or edges) E1 and E2, respectively, of the first region I may be less than a difference between two distances measured from the 4-1 region IV-1 or the 4-3 region IV-3 to the first and second edge portions (or edges) E1 and E2, respectively, of the first region I (refer to differences in lengths of arrows in FIG. 3). For example, the 4-2 region IV-2 may be located at a central portion in the third direction D3 of the first region I, while the 4-1 and 4-3 regions IV-1 and IV-3 are located at lateral portions in the third direction D3 of the first region I.

The first substrate 100 may include a field region on which an isolation pattern 110 is disposed and an active region 101 on which no isolation patterns are disposed. The isolation pattern 110 may include, for example, an oxide such as silicon oxide.

The peripheral circuit pattern may include a transistor TR and a wiring structure WS electrically connected thereto. The transistor TR may be disposed on the active region 101. Each component of the wiring structure WS may be formed by a patterning process or a damascene process.

The first insulating interlayer 150 may be disposed on the first substrate 100 and may cover the transistor TR and the wiring structure WS. The first insulating interlayer 150 may include, for example, an oxide such as silicon oxide.

The first CSP 200 may be disposed on the first insulating interlayer 150. The first CSP 200 may include, for example, polysilicon doped with n-type impurities. Alternatively, the first CSP 200 may include a metal silicide layer and a polysilicon layer doped with n-type impurities sequentially stacked. The metal silicide layer may include, for example, tungsten silicide.

The sacrificial layer structure 250, the channel connection pattern 580, the support layer 260, and the support pattern 265 may be formed on the first CSP 200. For example, the support layer 260 may be formed on and contacting the sacrificial layer structure 250 and the channel connection pattern 580.

The channel connection pattern 580 may be disposed on the third region III of the first substrate 100 and may include an air gap therein. The sacrificial layer structure 250 may be disposed on the second and fourth regions II and IV of the first substrate 100.

The channel connection pattern 580 may include, for example, polysilicon doped with n-type impurities or undoped polysilicon. The sacrificial layer structure 250 may include first to third sacrificial layers 220, 230 and 240 sequentially stacked in the first direction D1. The first and third sacrificial layers 220 and 240 may include, for example, an oxide such as silicon oxide, and the second sacrificial layer 230 may include, for example, a nitride such as silicon nitride.

Referring also to FIG. 10, the support layer 260 may be disposed on the channel connection pattern 580 and the sacrificial layer structure 250. In example embodiments, the support layer 260 may also be disposed in a first opening that extends through the channel connection pattern 580 and the sacrificial layer structure 250 and exposes an upper surface of the first CSP 200. For example, the support layer 260 may contact the upper surface of the first CSP 200 that is exposed by the first opening. The support layer 260 may include the support pattern 265 which is a portion of the support layer 260 disposed in the first opening. The support pattern 265 may be disposed in various layouts in a plan view. In example embodiments, the support pattern 265 may surround the third region III of the first substrate 100, in a plan view.

Each of the support layer 260 and the support pattern 265 may include a material having an etching selectivity with respect to the first, second, and third sacrificial layers 220, 230, and 240, for example, polysilicon doped with n-type impurities.

The gate electrode structure may be disposed on the first CSP 200 and the sacrificial layer structure 250 on the second and third regions II and III of the first substrate 100. The gate electrode structure may include gate electrodes, which may be disposed at a plurality of levels, respectively, spaced apart from each other in the first direction D1 and extend, e.g., lengthwise, in the second direction D2. In example embodiments, a plurality of gate electrode structures may be disposed and separated from each other in the third direction D3 by the first separation pattern 610.

In example embodiments, the gate electrode structure may include first and second gate electrodes 600 and 650 stacked in the first direction D1. The first gate electrodes 600 may be disposed at a plurality of levels, respectively, and the second gate electrodes 650 may be disposed at one or more levels on the first gate electrodes 600.

In example embodiments, first ones of the first gate electrodes 600 disposed at a lowermost level and a second level from a bottom may be gate induced drain leakage (GIDL) gate electrodes. In example embodiments, a second one of the first gate electrodes 600 disposed at a third level from the bottom may serve as a ground selection line (GSL). In example embodiments, third ones of the first gate electrodes 600 disposed at an uppermost level and a second level from a top may be GIDL gate electrodes. In example embodiments, fourth ones of the first gate electrodes 600 disposed at the other levels may serve as word lines. In example embodiments, the second gate electrode 650 may serve as a string selection line (SSL).

A first gate electrode 600 may include a gate conductive pattern and a gate barrier pattern at least partially covering a surface of the gate conductive pattern. The gate conductive pattern may include, for example, a metal having a low electrical resistance such as tungsten, titanium, tantalum, platinum, etc., and the gate barrier pattern may include, for example, a metal nitride such as titanium nitride, tantalum nitride, etc.

In example embodiments, the second gate electrode 650 may include, for example, polysilicon doped with n-type impurities.

In example embodiments, a plurality of first insulting patterns 275 may be disposed/stacked in the first direction D1, and each of the first insulating patterns 275 may be disposed between the first gate electrodes 600, or between the first one of the first gate electrodes 600 disposed at the lowermost level and the first CSP 200. The first insulating pattern 275 may include, for example, an oxide such as silicon oxide.

In example embodiments, the first separation pattern 610 may be disposed between the first gate electrodes 600 included in the gate electrode structures adjacent to each other in the third direction D3, and may extend on the first CSP 200 on the third and second regions III and II of the first substrate 100 to separate the first gate electrodes 600 from each other.

In example embodiments, the first separation pattern 610 may extend through the second insulating interlayer 290, the first gate electrodes 600, the first insulating patterns 275, and an upper portion of the first CSP 200. In example embodiments, the first separation pattern 610 may extend, e.g., lengthwise, in the second direction D2, and a plurality of first separation patterns 610 may be spaced apart from each other in the third direction D3.

In example embodiments, the gate electrode structure disposed on the third region III of the first substrate 100 and the memory channel structure MC extending through the gate electrode structure may collectively form a memory block. In example embodiments, a plurality of memory blocks may be spaced apart from each other in the third direction D3 on the third region III.

The second separation pattern 660 may extend, e.g., lengthwise, in the second direction D2 on the third region III of the first substrate 100 and a portion of the second region II of the first substrate 100 adjacent the third region III, and may extend through the second gate electrode 650 and an etch stop layer 640 to contact an upper surface of the fourth insulating interlayer 630. In example embodiments, the second separation pattern 660 may be disposed between a pair of the first separation patterns 610 adjacent to each other in the third direction D3, e.g., in a plan view.

Each of the first and second separation patterns 610 and 660 may include, for example, an oxide such as silicon oxide or, for example, an insulating nitride such as silicon nitride.

The cell structure CS may include a plurality of memory channel structures MC including first and second memory channel structures 550 and 720.

Referring to FIGS. 10 and 20, the first memory channel structure 550 may be disposed on the third region III of the first substrate 100 and may contact the upper surface of the first CSP 200, and may extend through the second insulating interlayer 290, the first gate electrodes 600, and the first insulating patterns 275 in a corresponding memory block.

In example embodiments, the first memory channel structure 550 may include a first filling pattern 530 of a pillar shape extending lengthwise in the first direction D1, a first channel 520 of a cup shape covering a sidewall and a lower surface of the first filling pattern 530, a first charge storage structure 510 on an outer sidewall and a lower surface of the first channel 520, and a first capping pattern 540 contacting upper surfaces of the first filling pattern 530, the first channel 520, and the first charge storage structure 510.

The first charge storage structure 510 may include a first tunnel insulating pattern 500, a first charge storage pattern 490, and a first blocking pattern 480 sequentially stacked in the horizontal direction or a radial direction from the outer sidewall of the first channel 520.

The second memory channel structure 720 may include a second filling pattern 700, a second channel 690, a second charge storage structure 680, and a second capping pattern 710 corresponding to the first memory channel structure 550. In example embodiments, the second memory channel structure 720 may extend through the fourth insulating interlayer 630, the etch stop layer 640, and the second gate electrode 650, and may contact an upper surface of the first memory channel structure 550.

In example embodiments, the second channel 690 may include a lower portion extending through and horizontally overlapping the fourth insulating interlayer 630 and having a first width, a central portion extending through and horizontally overlapping the etch stop layer 640 and having a second width, and an upper portion extending through and horizontally overlapping a portion of the second gate electrode 650 and having a third width. Each of the first and third widths may be greater than the second width. In example embodiments, the upper portion of the second channel 690 may have a cup shape, and the second filling pattern 700 may fill an inner space defined by or enclosed in the cup shape of the upper portion of the second channel 690.

The second charge storage structure 680 may extend in the vertical direction through the second gate electrode 650 and may cover/contact a sidewall of the upper portion of the second channel 690, an edge portion of a lower surface of the upper portion of the second channel 690, and a sidewall of the second capping pattern 710. The lower surface of the upper portion of the second channel 690 may be a downward facing portion of the surface of the upper portion of the second channel 690. The second charge storage structure 680 may include a second tunnel insulating pattern, a second charge storage pattern, and a third blocking pattern, corresponding to those of the first charge storage structure 510, respectively, that are sequentially stacked in the horizontal direction or a radial direction from an outer sidewall of the second channel 690.

The second capping pattern 710 may contact upper surfaces of the second filling pattern 700 and the upper portion of the second channel 690, and also contact an inner sidewall of the second charge storage structure 680.

In example embodiments, a plurality of memory channel structures MC may be spaced apart from each other in each of the second and third directions D2 and D3 within each of the memory blocks to form a memory channel structure array MCA. A plurality of first memory channel structures 550 included in the memory channel structure array MCA may be electrically connected to each other by a corresponding one of the channel connection patterns 580. For example, the first charge storage structure 510 may not be disposed on a portion of the outer sidewall of each first channel 520, and the channel connection pattern 580 may contact the outer sidewalls of the first channels 520 to electrically connect the first channels 520 to each other.

The memory channel structure array MCA may include memory channel structure rows MCR spaced apart from each other in the second direction D2. Each of the memory channel structure rows MCR may include a plurality of the memory channel structures MC disposed in or arranged along the third direction D3.

The first and second channels 520 and 690 may include, for example, undoped polysilicon. The first and second filling patterns 530 and 700 may include, for example, an oxide such as silicon oxide. The first and second capping patterns 540, 710 may include, for example, polysilicon doped with n-type impurities.

The first tunnel insulating pattern 500 and the second tunnel insulating pattern may include, for example, an oxide such as silicon oxide. The first charge storage pattern 490 and the second charge storage pattern may include, for example, a nitride such as silicon nitride. The first blocking pattern 480 and the third blocking pattern may include, for example, an oxide such as silicon oxide.

The second blocking pattern 590 may cover upper and lower surfaces of each of the first gate electrodes 600 and a portion of a sidewall of the gate electrode 600 facing the first memory channel structure 550. The second blocking pattern 590 may include, for example, a metal oxide such as aluminum oxide or hafnium oxide.

The mold structure MS may be disposed on the sacrificial layer structure 250 on the fourth region IV of the first substrate 100. The mold structure MS may include the first insulating patterns 275 and fourth sacrificial patterns 285 alternately stacked in the first direction D1 on the sacrificial layer structure 250. The fourth sacrificial patterns 285 may include, for example, a nitride such as silicon nitride.

The second insulating interlayer 290 may be disposed on an uppermost one of the first insulating patterns 275. The third insulating interlayer 620 may be disposed on the second insulating interlayer 290. The third insulating interlayer 620 may cover/contact sidewalls of the fourth insulating interlayer 630, the etch stop layer 640, and the second gate electrodes 650. The second and third insulating interlayers 290 and 620 may include, for example, an oxide such as silicon oxide.

The through-via 725 may extend lengthwise in a vertical direction through the second and third insulating interlayers 290 and 620, the mold structure MS, the support layer 260, the sacrificial layer structure 250, the first CSP 200, and an upper portion of the first insulating interlayer 150 on the fourth region IV of the first substrate 100, and may contact the wiring structure WS to be electrically connected to the transistor TR. For example, the through-via 725 may provide electrical connection between a corresponding one of the first bit line structure 797, the 1-2 bit line 775-2 and the third bit line structure 799, and a corresponding one of the transistors TR of the peripheral circuit structure PS.

In example embodiments, a plurality of through-vias 725 may be spaced apart from each other in each of the second and third directions D2 and D3 on the fourth region IV of the first substrate 100.

The fifth insulating interlayer 750 may be disposed on the second memory channel structures 720, the through-vias 725, and the third insulating interlayer 620. The first via 755 may extend in a vertical direction through the fifth insulating interlayer 750 to contact an upper surface of the second memory channel structure 720. The first via 755 may provide electrical connection between the memory channel structure MC and the bit line.

In example embodiments, a plurality of first vias 755 may be spaced apart from each other in each of the second and third directions D2 and D3 corresponding to the second memory channel structures 720.

FIG. 4 shows that the memory channel structure MC and the bit line are electrically connected to each other through a single via, however, the embodiments are not limited thereto. For example, the memory channel structure MC and the bit line may be electrically connected to each other through a plurality of vias, a plurality of wirings, and/or a plurality of pads. Hereinafter, for convenience of description, explanation is given on the assumption that the bit line is electrically connected to the memory channel structure MC through a single via, e.g., the first via 755.

The first bit line structure 797 may include the 1-1 bit line 775-1 and the 2-1 bit line 795-1 sequentially stacked in the first direction D1. The third bit line structure 799 may include the 1-3 bit line 775-3 and the 2-2 bit line 795-2 sequentially stacked in the first direction D1.

In example embodiments, a plurality of first basic units RU1 each of which may include two 1-2 bit lines 775-2, a first bit line structure 797, and a third bit line structure 799 arranged in an order of one 1-2 bit line 775-2, the first bit line structure 797, the other 1-2 bit line 775-2, and the third bit line structure 799 may be disposed in the second direction D2 in the semiconductor device. In example embodiments, the first bit line structure 797, the 1-2 bit lines 775-2, and the third bit line structure 799 may be commonly connected to the memory channel structures MC included in a corresponding one of the memory channel rows MCR.

In example embodiments, the first bit line structure 797 may be electrically connected to the transistor TR of the peripheral circuit structure PS through the through-via 725 disposed on the 4-1 region IV-1 of the first substrate 100. In example embodiments, the 1-2 bit line 775-2 may be electrically connected to the transistor TR of the peripheral circuit structure PS through the through-via 725 disposed on the 4-2 region IV-2 of the first substrate 100. In example embodiments, the third bit line structure 799 may be electrically connected to the transistor TR of the peripheral circuit structure PS through the through-via 725 disposed on the 4-3 region IV-3 of the first substrate 100.

In example embodiments, the transistor TR of the peripheral circuit structure PS to which the first bit line structure 797, the 1-2 bit line 775-2, and the third bit line structure 799 are electrically connected may form a page buffer circuit.

Each of the 1-1, 1-2, and 1-3 bit lines 775-1, 775-2 and 775-3 may extend through the sixth insulating interlayer 770, and may extend lengthwise in the third direction D3 on the third and fourth regions III and IV of the first substrate 100. The 1-1, 1-2, and 1-3 bit lines 775-1, 775-2 and 775-3 may be spaced apart from each other in the second direction D2. In example embodiments, a plurality of basic units each of which may include a 1-1 bit line 775-1, two 1-2 bit lines 775-2, and a 1-3 bit line 775-3 arranged in an order of one 1-2 bit line 775-2, the 1-1 bit line 775-1, the other 1-2 bit line 775-2, and the 1-3 bit line 775-3 may be disposed in the second direction D2.

In example embodiments, widths in the second direction D2 of the 1-1, 1-2, and 1-3 bit lines 775-1, 775-2, and 775-3 may be substantially the same as each other.

Each of the 2-1 and 2-2 bit lines 795-1 and 795-2 may extend in the first direction D1 through the seventh insulating interlayer 790, may extend lengthwise in the third direction D3 on the third and fourth regions III and IV of the first substrate 100. The 2-1 and 2-2 bit lines 795-1 and 795-2 may be spaced apart from each other in the second direction D2. The 2-1 bit line 795-1 may contact an upper surface of the 1-1 bit line 775-1 and may extend lengthwise in the third direction D3. The 2-2 bit line 795-2 may contact an upper surface of the 1-3 bit line 775-3 and may extend lengthwise in the third direction D3. For example, the first and third bit line structures 797 and 799 electrically connected to the peripheral circuit structure PS through the through-via 725 disposed on the 4-1 and 4-3 regions IV-1 and IV-3 of the first substrate 100 adjacent to the first and second edge portions (or edges) E1 and E2 of the first region I of the first substrate 100 may further include the 2-1 and 2-2 bit lines 795-1 and 795-2, respectively, compared to the 1-2 bit line 775-2.

Hereinafter, for convenience of description, the 1-1, 1-2, and 1-3 bit lines 775-1, 775-2, and 775-3 may be collectively referred to as first bit lines 775, and the 2-1 and 2-2 bit lines 795-1 and 795-2 may be collectively referred to as second bit lines 795.

The sixth insulating interlayer 770 may be disposed on the fifth insulating interlayer 750 and the first via 755. The seventh insulating interlayer 790 may be disposed on the sixth insulating interlayer 770 and the first bit lines 775. The sixth and seventh insulating interlayers 770 and 790 may include, for example, an oxide such as silicon oxide.

In example embodiments, an upper surface of the first bit line 775 may have a first width W1 in the second direction D2, a lower surface of the second bit line 795 may have a second width W2 in the second direction D2, and an upper surface of the second bit line 795 may have a third width W3 in the second direction D2. In example embodiments, the third width W3 may be greater than the first width W1. In example embodiments, the third width W3 may be greater than the second width W2. In example embodiments, the second width W2 may be less than the first width W1.

In example embodiments, an upper end of the 1-2 bit line 775-2 and an upper end of the 1-3 bit line 775-3 (or the upper end of the 1-2 bit line 775-2 and an upper end of the 1-1 bit line 775-1) may be spaced apart from each other by a first distance d1 in the second direction D2. For example, the upper ends of the bit lines may be top/upper surfaces of the bit lines. In example embodiments, the upper end of the 1-2 bit line 775-2 and a lower end or a lower/bottom surface of the second bit line 795 may be spaced apart from each other by a second distance d2 in the second direction D2.

In example embodiments, as described above, since the second width W2 of the lower surface of the second bit line 795 is less than the first width W1 of the upper surface of the first bit line 775, the second distance d2 between the 1-2 bit line 775-2 and the second bit line 795 may be greater than the first distance d1 between the 1-2 bit line 775-2 and the 1-3 bit line 775-3 (or between the 1-2 bit line 775-2 and the 1-1 bit line and 775-1). Accordingly, the 1-2 bit line 775-2 and the second bit line 795 may be sufficiently spaced apart from each other to reduce and/or prevent electrical short between the 1-2 bit line 775-2 and the second bit line 795.

In example embodiments, upper ends of neighboring ones of the first bit lines 775 may be spaced apart from each other by the first distance d1. Accordingly, the 1-2 bit line 775-2, the first bit line structure 797, the 1-2 bit line 775-2, and the third bit line structure 799 may be sequentially disposed by a constant distance in the second direction D2, e.g., in a plan view.

Each of the first and second bit lines 775 and 795 may include, for example, a metal such as copper (Cu), aluminum (Al), tungsten (W), or titanium (Ti), a metal nitride such as titanium nitride (TiN), tungsten nitride (WN), tantalum (Ta), tantalum nitride (TaN), and titanium aluminum nitride (TiAlN), or a combination thereof.

The page buffer pre-charges the bit line to a specific voltage (generally, about 0.7V to about 1.0V) during a read operation, and detects whether the voltage of the bit line is maintained or discharged depending on a state of a selected memory cell, thereby reading data. In addition, during a program verification operation, the page buffer pre-charges the bit line to accurately check the program state of the memory cell. Therefore, a connection structure between the page buffer and the bit line directly affects pre-charge performance, which in turn affects read and write speed, power consumption, and reliability of the memory device.

In particular, a connection position between the bit line and the page buffer has an important influence on pre-charge operation speed. Particularly, pre-charge efficiency of the bit line may vary depending on a position of the through-via. In a first one of the bit lines electrically connected to the page buffer through a first one of the through-vias contacting a central portion of the first one of the bit lines, pre-charge current may flow in both directions of the first one of the bit lines from the position of the first one of the through-vias, so as to have a relatively fast pre-charge speed. In a second one of the bit lines electrically connected to the page buffer through a second one of the through-vias contacting an edge portion of the second one of the bit lines, the pre-charge current may flow in one direction from the second one of the through-vias, so as to have a relatively slow pre-charge speed. The difference in pre-charge speed may affect timing margins during read and program verification operations of the memory device (refer to arrow lengths of FIG. 2).

According to example embodiments, the second bit lines 795 may be additionally disposed on the 1-1 and 1-3 bit lines 775-1 and 775-3, e.g., without an intervening layer, which may be connected to the page buffer circuit through the through-vias 725 disposed on the 4-1 and 4-3 regions IV-1 and IV-3 of the first substrate 100 disposed at opposite ends of the first region I of the first substrate 100 in the second direction D2. For example, unlike a conventional single-layered bit line structure, the bit line structure in accordance with example embodiments may have a stacked structure including two bit lines vertically stacked at two levels, respectively, with respect to the same electrical connection path. The bit line structure having the stacked structure may have an increased cross-sectional area of the bit line structure, so as to have a reduced resistance and a reduced RC delay. Thus, the pre-charge current may quickly propagate throughout the entire bit line structure, and the pre-charge speed of the bit line structure may be enhanced/improved, so that overall operation speed of memory cells may be increased. Since overall operation speed of the memory device is limited by the pre-charge speed of the bit line structure when it is the slowest speed in the memory device, such improvement may directly affect/improve overall system performance.

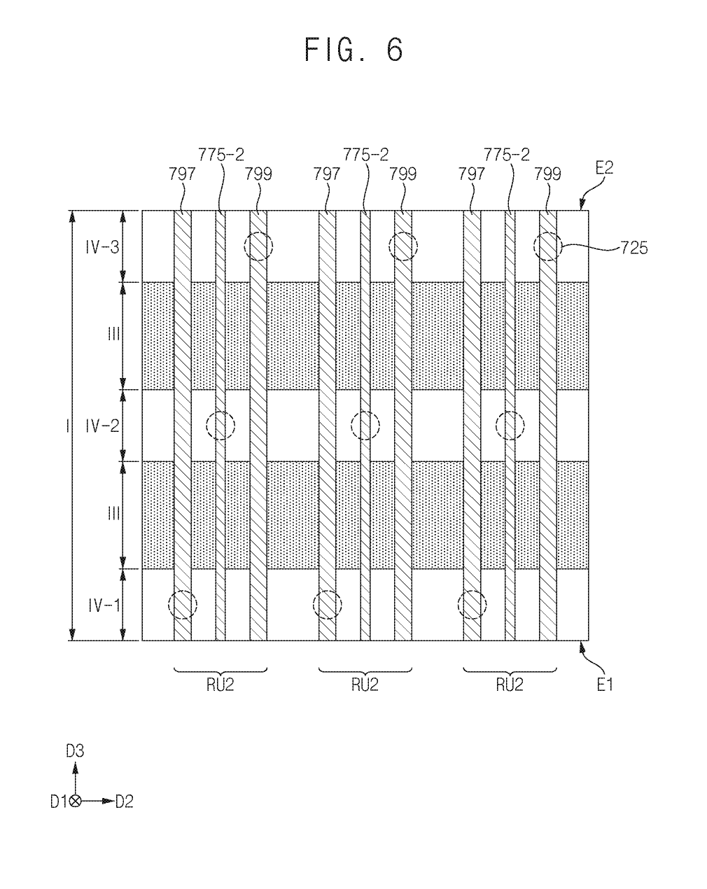

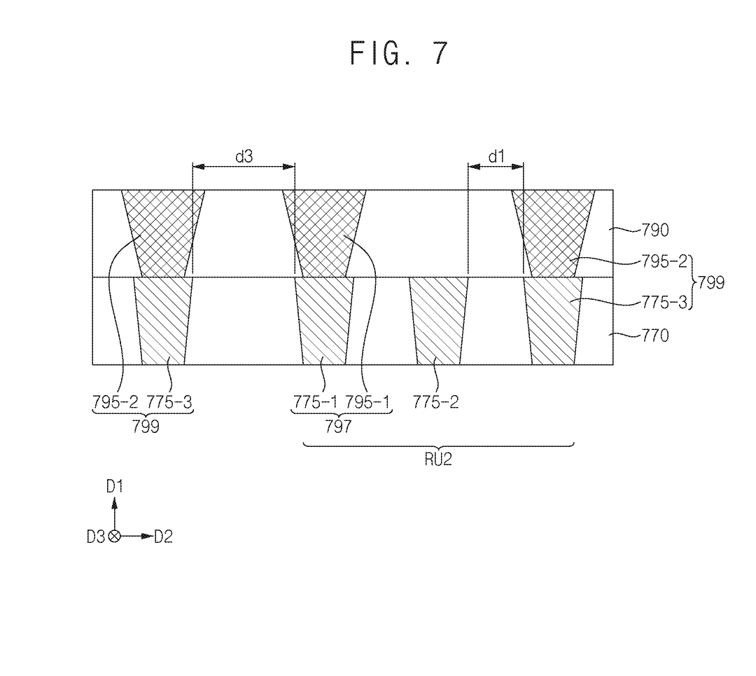

FIGS. 6 and 7 are a plan view showing a layout and a cross-sectional view, respectively, illustrating a semiconductor device in accordance with example embodiments, which may correspond to FIGS. 2 and 5, respectively. This semiconductor device is substantially the same as the semiconductor device described with reference to FIGS. 1-5, except for a layout of the bit lines, and thus redundant description is omitted herein.

Referring to FIGS. 6 and 7, a plurality of second basic units RU2 each of which may include the first bit line structure 797, the 1-2 bit line 775-2, and the third bit line structure 799 which are sequentially arranged may be disposed/repeated in the second direction D2 in the semiconductor device.

In example embodiments, a plurality of basic units each of which may include the 1-1 bit line 775-1, the 1-2 bit line 775-2, and the 1-3 bit line 775-3 may be disposed in the second direction D2.

In example embodiments, an upper surface/end of the 1-1 bit line 775-1 and an upper surface/end of the 1-3 bit line 775-3 may be spaced apart from each other by a third distance d3 in the second direction D2.

In example embodiments, the third distance d3 between the 1-1 bit line 775-1 and the 1-3 bit line 775-3 may be greater than the first distance d1 between the 1-2 bit line 775-2 and the 1-3 bit line 775-3 (or between the 1-2 bit line 775-2 and the 1-1 bit line 775-1). Accordingly, neighboring ones of the first and third bit line structures 797 and 799 may be spaced apart from each other in the second direction D2 by a sufficiently large distance.

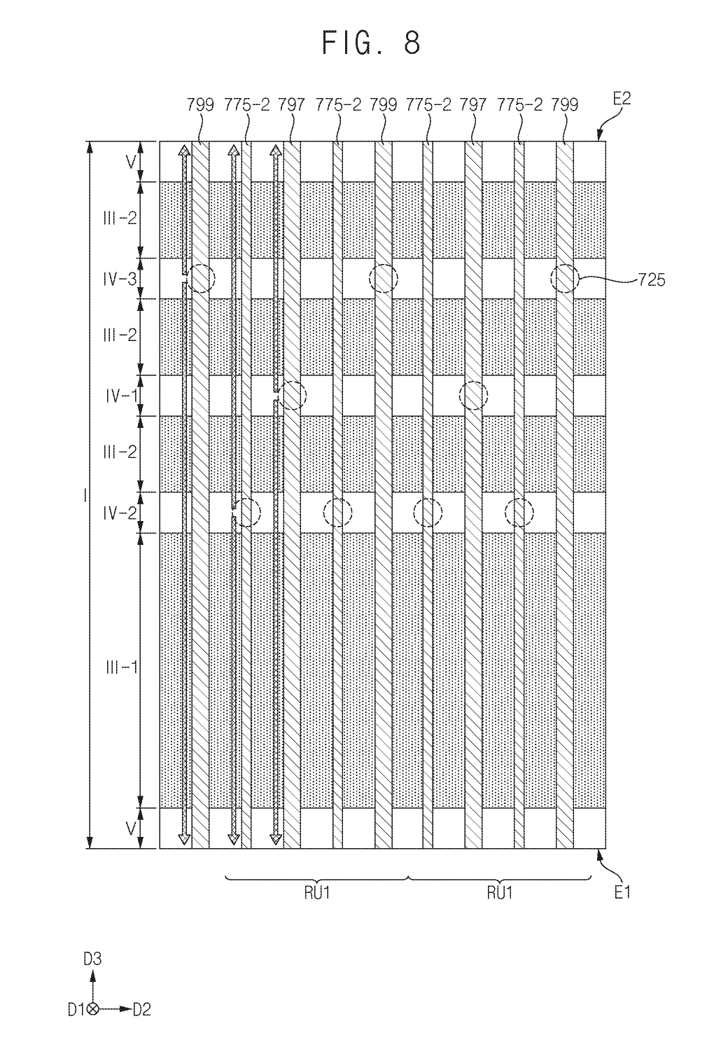

FIG. 8 is a planar layout or a plan view illustrating a semiconductor device in accordance with example embodiments, which may correspond to FIG. 2. This semiconductor device is substantially the same as the semiconductor device described with reference to FIGS. 1-5, except for layouts of the third and fourth regions III and IV of the first substrate 100, and thus redundant description is omitted herein.

Referring to FIG. 8, the first region I of the first substrate 100 may further include fifth regions V adjacent to the first and second edge portions (or edges) E1 and E2, respectively. Each of the fifth regions V may be a dummy memory region.

In example embodiments, one of the third regions III adjacent to the first edge portion E1 may be a 3-1 region (e.g., a third primary region) III-1, and other ones of the third regions III may be 3-2 regions (e.g., third secondary regions) III-2. In example embodiments, the first region I may include the fifth region V, the 3-1 region III-1, the 4-2 region IV-2, the 3-2 region III-2, the 4-1 region IV-1, the 3-2 region III-2, the 4-3 region IV-3, the 3-2 region III-2, and the fifth region V sequentially disposed in the third direction D3 from the first edge portion E1.

In example embodiments, a difference between two distances measured from the 4-2 region IV-2 to the first and second edge portions (or edges) E1 and E2, respectively, of the first region I in the third direction D3 may be less than a difference between two distances measured from the 4-1 region IV-1 or the 4-3 region IV-3 to the first and second edge portions (or edges) E1 and E2, respectively, of the first region I in the third direction D3 (refer to a differences in lengths of arrows in FIG. 8). For example, the 4-2 region IV-2 may be closer to a central portion in the third direction D3 of the first region I than the 4-1 and 4-3 regions IV-1 and IV-3.

In example embodiments, widths in the third direction D3 of the 3-2 regions III-2 may be substantially the same as each other, or may differ within a range of about ±20%. In example embodiments, a width in the third direction D3 of the 3-1 region III-1 may be greater than a sum of widths of the 3-2 regions III-2.

For example, the first and second bit line structures 797 and 799 electrically connected to the peripheral circuit structure PS through the through-vias 725 disposed on the 4-1 and 4-3 regions IV-1 and IV-3, which are relatively close/adjacent to the second edge portion or the second edge E2 of the first region I may further include the second bit lines 795 compared to the 1-2 bit lines 775-2.

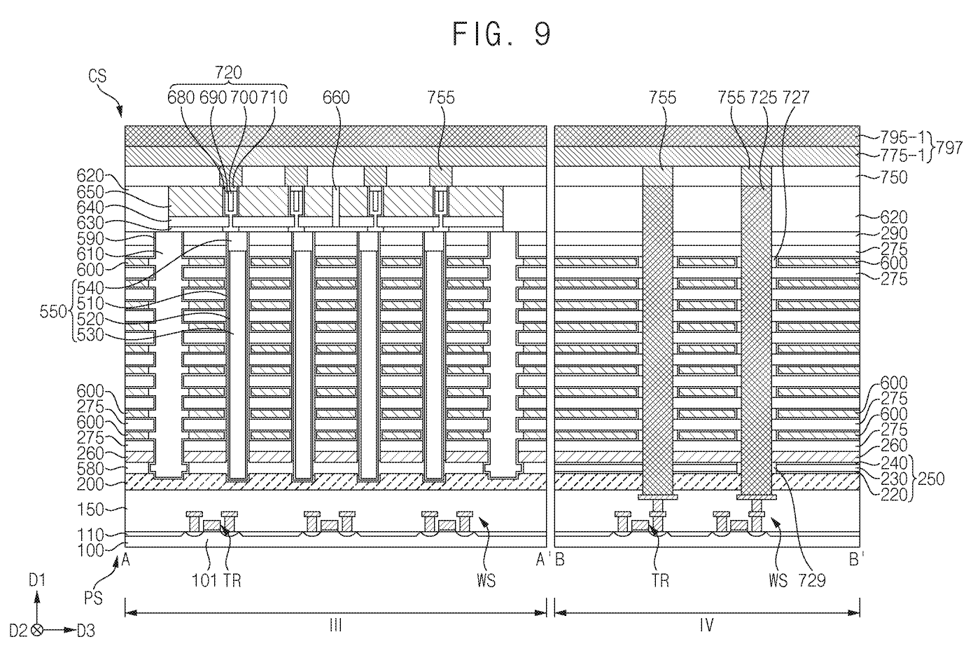

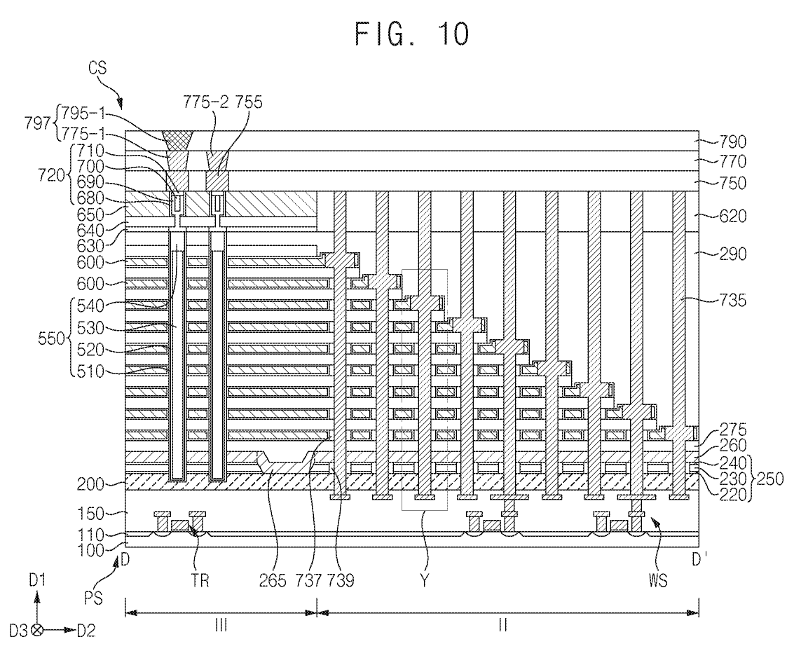

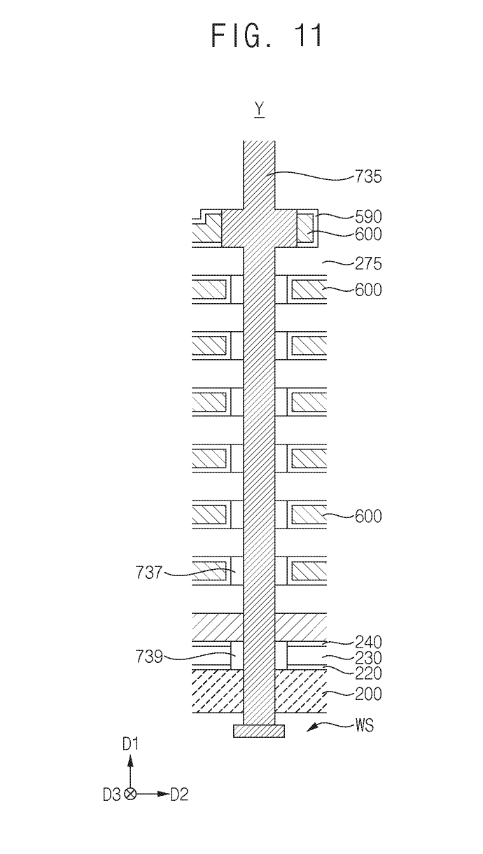

FIG. 9 is a cross-sectional view illustrating a semiconductor device in accordance with example embodiments, which may correspond to FIG. 4. This semiconductor device is substantially the same as the semiconductor device described with reference to FIGS. 1-5, except that the first gate electrodes 600 and second and third insulating patterns 727 and 729 are disposed on the fourth regions IV of the first substrate 100 instead of the fourth sacrificial patterns 285 of the mold structure MS, and thus redundant description is omitted herein.

Referring to FIG. 9, the first gate electrodes 600 may be sequentially stacked in the first direction D1 on the sacrificial layer structure 250 on the fourth region IV of the first substrate 100.

Each of the through-vias 725 may extend through the second, third and fifth insulating interlayers 290, 620 and 750, the first insulating patterns 275, the first gate electrodes 600, the support layer 260, the sacrificial layer structure 250, the first CSP 200, and the upper portion of the first insulating interlayer 150 on the fourth regions IV of the first substrate 100 to contact the wiring structure WS of the peripheral circuit pattern. In example embodiments, each of the through-vias 725 may be spaced apart from and insulated from the first gate electrodes 600 by the second insulation patterns 727, and may be spaced apart from and insulated from the sacrificial layer structure 250 by the third insulation pattern 729. Each of the second and third insulating patterns 727 and 729 may include, for example, an oxide such as silicon oxide.

FIGS. 10 and 11 are cross-sectional views illustrating a semiconductor device in accordance with example embodiments. Particularly, FIG. 10 is a cross-sectional view taken along a line D-D' of FIGS. 1, and 11 is an enlarged cross-sectional view of a region Y of FIG. 10. This semiconductor device is substantially the same as the semiconductor device described with reference to FIGS. 1-5, except for further including first contact plugs 735, and thus redundant description is omitted herein.

Referring to FIGS. 10 and 11, the gate electrode structure may have a staircase shape in which lengths of gate electrodes in the second direction D2 decreases in the first direction D1 receding from a lowermost level and approaching an uppermost level, and accordingly may include steps disposed (ascending/descending) in the second direction D2 on the second region II of the first substrate 100. In addition, the gate electrode structure may further include steps disposed (ascending/descending) in the third direction D3 on the second region II of the first substrate 100.

Hereinafter, an end portion of each of the first gate electrodes 600 corresponding to the step of the gate electrode structure, e.g., a portion of each of the first gate electrodes 600 not covered by other ones of the first gate electrodes 600 thereover is referred to as a pad. Accordingly, the pad of each of the first gate electrodes 600 may be disposed on the second region II of the substrate 100. In example embodiments, the pad of each of the first gate electrodes 600 may have a greater thickness than other portions of the same/corresponding first gate electrode 600.

Each of the first contact plugs 735 may extend through the second and third insulating interlayers 290 and 620, the first gate electrodes 600, the first insulating patterns 275, the support layer 260, the sacrificial layer structure 250, the first CSP 200, and the upper portion of the first insulating interlayer 150 to contact the wiring structure WS.

In example embodiments, each of the first contact plugs 735 may extend through a pad of a first one of the first gate electrodes 600 and through second ones of the first gate electrodes 600 thereunder. In example embodiments, each of the first contact plugs 735 may be spaced apart from and insulated from the second ones of the first gate electrodes 600 by fourth insulating patterns 737, and may be spaced apart from and insulated from the sacrificial layer structure 250 by a fifth insulating pattern 739. In example embodiments, the fourth insulating pattern 737 may not be disposed between each of the first contact plugs 735 and the corresponding first one of the first gate electrodes 600. For example, each of the first contact plugs 735 may contact a corresponding pad of the first gate electrodes 600.

In example embodiments, each of the first contact plugs 735 may have a protrusion protruding in the horizontal direction on a sidewall at a level where the first one of the first gate electrodes 600 is placed, and the protrusion may contact the first one of the first gate electrodes 600.

Each of the fourth and fifth insulating patterns 737 and 739 may include, for example, an oxide such as silicon oxide.

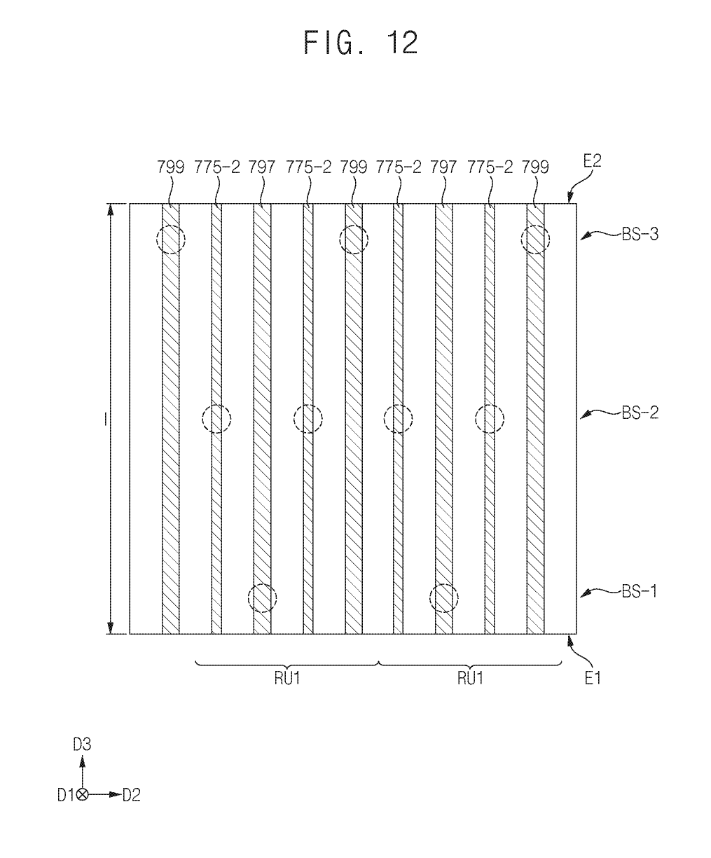

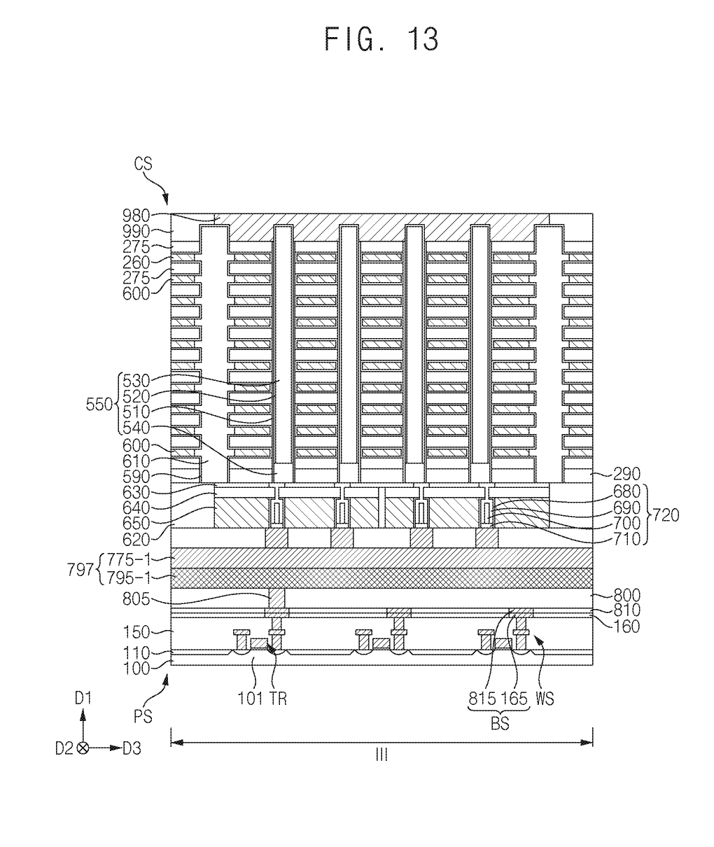

FIGS. 12 and 13 are a planar layout view and a cross-sectional view, respectively, illustrating a semiconductor device in accordance with example embodiments. This semiconductor device is substantially the same as the semiconductor device described with reference to FIGS. 1-5, except that the cell structure CS and the peripheral circuit structure PS are bonded to each other through a bonding structure, and thus redundant description is omitted herein.

Referring to FIGS. 12 and 13, the bonding structure may be disposed between the peripheral circuit structure PS and the cell structure CS. For example, the peripheral circuit structure PS, the bonding structure, and the cell structure CS may be sequentially stacked in the first direction D1.

The bonding structure may include a first bonding layer 160 disposed on the peripheral circuit structure PS and first bonding patterns 165 in the first bonding layer 160, and a second bonding layer 810 disposed under the cell structure CS and second bonding patterns 815 disposed in the second bonding layer 810 and contacting the first bonding patterns 165, respectively. The first and second bonding patterns 165 and 815 may collectively form a bonding pattern structure BS, and a plurality of bonding pattern structures BS may be spaced apart from each other in each of the second and third directions D2 and D3. In example embodiments, the bonding pattern structures BS may include a first bonding pattern structure BS-1, a second bonding pattern structure BS-2 and a third bonding pattern structure BS-3.

The first bonding pattern structures BS-1 may be adjacent to the first edge portion E1 of the first region I of the first substrate 100, and may be spaced apart from each other in the second direction D2. The third bonding pattern structures BS-3 may be adjacent to the second edge portion E2 of the first region I of the first substrate 100, and may be spaced apart from each other in the second direction D2. The second bonding pattern structures BS-2 may be disposed between the first and third bonding pattern structures BS-1 and BS-3, may be disposed adjacent to the central portion in the third direction D3 of the first region I of the first substrate 100, and may be spaced apart from each other in the second direction D2.

In example embodiments, a plurality of basic units each of which may include a first one of the second bonding pattern structures BS-2 in the central portion of the first region I, the first bonding pattern structure BS-1 adjacent to the first edge portion E1, a second one of the second bonding pattern structures BS-2 in the central portion of the first region I, and the third bonding pattern structure BS-3 adjacent to the second edge portion E2 may be disposed in or arranged along the second direction D2. For example, the bonding pattern structures BS may be sequentially disposed in the second direction D2 to be adjacent to the central portion of the first region I, the first edge portion E1 of the first region I, the central portion of the first region I, and the second edge portion E2 of the first region I.

The cell structure CS may have an upside-down structure compared to the cell structure CS of the semiconductor device described with reference to FIGS. 1-5. In addition, the cell structure CS may not include the first CSP 200, the channel connection patterns 580, the support layer 260, and the support pattern 265, compared to the cell structure CS of the semiconductor device described with reference to FIGS. 1-5. Furthermore, the cell structure CS may further include an eighth insulating interlayer 800, second vias 805, second CSPs 980, and a ninth insulating interlayer 990 compared to the cell structure CS of the semiconductor device described with reference to FIGS. 1-5.

Hereinafter, each component of the cell structure CS having the upside-down structure is described.

The eighth insulating interlayer 800 may be disposed on the bonding structure. The eighth insulating interlayer 800 may include, for example, an oxide such as silicon oxide.

Each of the second vias 805 may extend through the eighth insulating interlayer 800 to electrically connect each of the bit lines and a corresponding one of the bonding pattern structures BS. FIG. 13 shows that each of the bit lines and corresponding one of the bonding pattern structures BS are electrically connected to each other through a single via, however the embodiments are not limited thereto, and may be electrically connected to each other through a plurality of vias, a plurality of wirings, and/or a plurality of pads.

The first bit line structures 797, the 1-2 bit lines 775-2, and the third bit line structures 799 may be disposed on the eighth insulating interlayer 800.

In example embodiments, a plurality of first basic units RU1 each of which may include an arrangement of the 1-2 bit line 775-2, the first bit line structure 797, the 1-2 bit line 775-2, and the third bit line structure 799 (e.g., as shown in FIG. 12) may be disposed in the second direction D2.

The first and second bit line structures 797 and 799 electrically connected to the peripheral circuit structure PS through the first and third bonding pattern structures BS-1 and BS-3 adjacent to the first and second edge portions E1 and E2, respectively, of the first region I of the first substrate 100 may further include the second bit lines 795 compared to the 1-2 bit lines 775-2.

In example embodiments, the first bit line structures 797 may be electrically connected to the transistors TR of the peripheral circuit structure PS through the first bonding pattern structures BS-1. In example embodiments, the 1-2 bit lines 775-2 may be electrically connected to the transistors TR of the peripheral circuit structure PS through the second bonding pattern structures BS-2. In example embodiments, the third bit line structures 799 may be electrically connected to the transistors TR of the peripheral circuit structure PS through the third bonding pattern structures BS-3.

The gate electrode structures and the memory channel structures MC extending through the gate electrode structures may be disposed on the first bit line structures 797, the 1-2 bit lines 775-2, and the third bit line structures 799.

The plurality of first memory channel structures 550 included in the memory channel structure array MCA may be electrically connected to each other by a corresponding one of the second CSPs 980. Particularly, the first charge storage structure 510 may not be disposed on upper outer sidewalls and upper surfaces of the first channels 520, and each of the second CSPs 980 may contact the upper outer sidewalls and the upper surfaces of the first channels 520 to electrically connect the first channels 520 to each other.

The second CSPs 980 may include, for example, polysilicon doped with n-type impurities. Alternatively, the second CSPs 980 may include a metal silicide layer and a polysilicon layer doped with n-type impurities sequentially stacked. In example embodiments, the metal silicide layer may include, for example, tungsten silicide.

The ninth insulating interlayer 990 may be disposed on the gate electrode structures and may cover sidewalls of the second CSPs 980. The ninth insulating interlayer 990 may include, for example, an oxide such as silicon oxide.

In example embodiments, the 1-2 bit line 775-2, the first bit line structure 797, the 1-2 bit line 775-2, and the third bit line structure 799 may be sequentially disposed by a constant distance in the second direction D2, e.g., in a plan view.

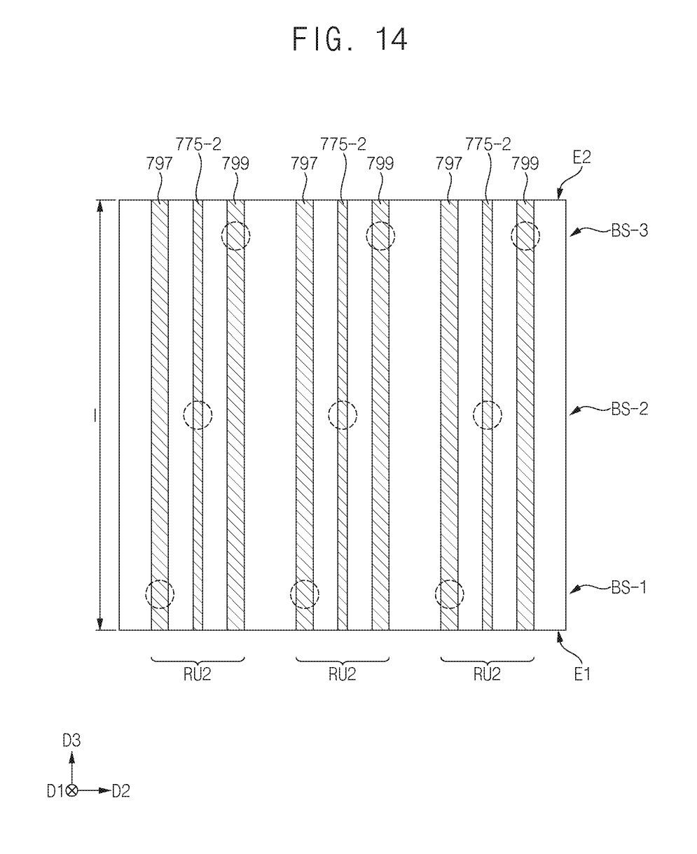

FIG. 14 is a planar layout view illustrating a semiconductor device in accordance with example embodiments. This semiconductor device is substantially the same as the semiconductor device described with reference to FIGS. 12 and 13, except for layouts of the bonding pattern structures BS and the bit lines, and thus redundant description is omitted herein.

Referring to FIG. 14, the first bonding pattern structure BS-1, the second bonding pattern structure BS-2, and the third bonding pattern structure BS-3 may be alternately and/or repeatedly disposed in the second direction D2. For example, a plurality of basic units each of which may include the first bonding pattern structure BS-1, the second bonding pattern structure BS-2, and the third bonding pattern structure BS-3 may be disposed in or arranged along the second direction D2.

In example embodiments, the plurality of second basic units RU2 each of which may include the first bit line structure 797, the 1-2 bit line 775-2, and the third bit line structure 799 may be disposed in the second direction D2.

In example embodiments, similar to the semiconductor device described with reference to FIGS. 6 and 7, the upper end of the 1-1 bit line 775-1 and the upper end of the 1-3 bit line 775-3 may be spaced apart from each other by the third distance d3 in the second direction D2. In example embodiments, similar to the semiconductor device described with reference to FIGS. 6 and 7, the third distance d3 between the 1-1 bit line 775-1 and the 1-3 bit line 775-3 may be greater than the first distance d1 between the 1-2 bit line 775-2 and the 1-3 bit line 775-3 (or between the 1-2 bit line 775-2 and the 1-1 bit line 775-1). Accordingly, neighboring ones of the first and third bit line structures 797 and 799 may be spaced apart from each other in the second direction D2 by a sufficiently large distance.

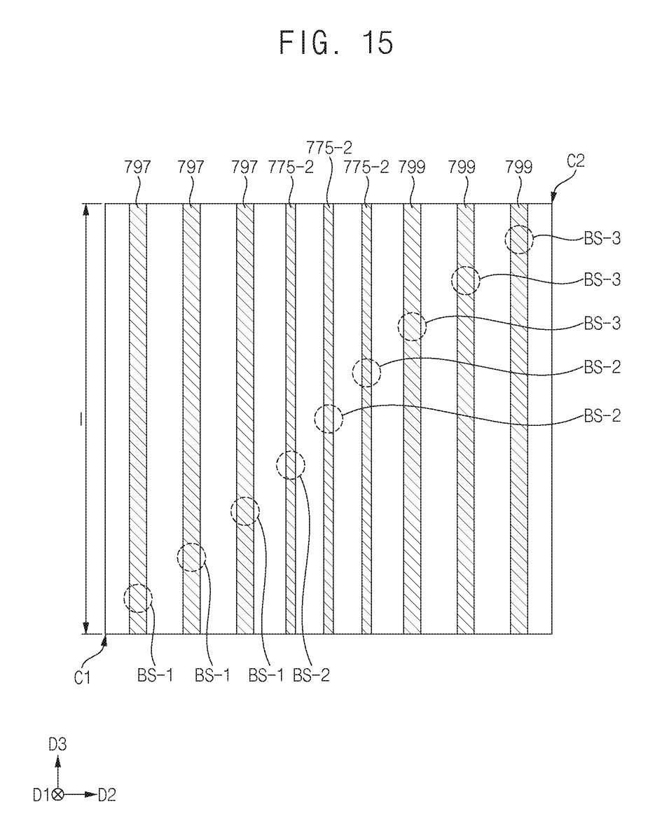

FIG. 15 is a planar layout view illustrating a semiconductor device in accordance with example embodiments. This semiconductor device is substantially the same as the semiconductor device described with reference to FIGS. 12 and 13, except for layouts of the bonding pattern structures BS and the bit lines, and thus redundant description is omitted herein.

Referring to FIG. 15, the bonding pattern structures BS may be disposed along a diagonal (e.g., from a lower-left corner to an upper-right corner) of the first region I. The first bonding pattern structure BS-1 among the bonding pattern structures BS may be disposed at a first corner C1 of the first region I. The second bonding pattern structure BS-2 among the bonding pattern structures BS may be disposed at a central portion of the first region I. The third bonding pattern structure BS-3 among the bonding pattern structures BS may be disposed at a second corner C2 of the first region I facing/opposite the first corner C1.

In example embodiments, the semiconductor device may have a layout in which the first bit line structure 797 electrically connected to the first bonding pattern structure BS-1 disposed at the first corner C1 is disposed at a first side of the 1-2 bit lines 775-2 disposed side by side in the second direction D2, and the third bit line structure 799 electrically connected to the third bonding pattern structure BS-3 disposed at the second corner C2 is disposed at a second side of the 1-2 bit lines 775-2.

In example embodiments, a plurality of 1-2 bit lines 775-2 may be spaced apart from each other in the second direction by a distance that is less than a distance in the second direction D2 between the first bit line structures 797 or between the third bit line structures 799.

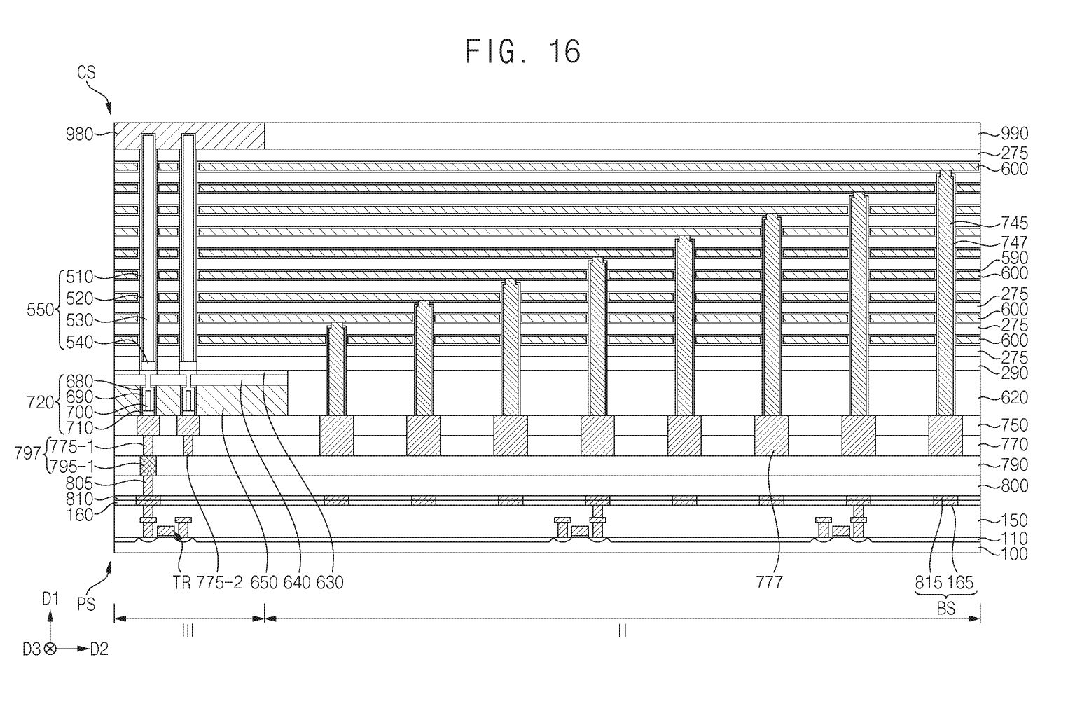

FIG. 16 is a cross-sectional view illustrating a semiconductor device in accordance with example embodiments. The semiconductor device is substantially the same as the semiconductor device described with reference to FIGS. 12-13, except that the semiconductor device further includes a second contact plug 745, and thus redundant description is omitted herein.

Referring to FIG. 16, a plurality of second contact plugs 745 may be disposed in the second direction D2, and each of the second contact plugs 745 may extend through the third and second insulating interlayers 620 and 290, the first gate electrodes 600, and the second blocking pattern 590 on the second region II of the first substrate 100, and may contact a lower surface of a corresponding one of the first gate electrodes 600 (hereinafter referred to as a selected gate electrode) to be electrically connected thereto.

A spacer 747 may cover a sidewall of each of the second contact plugs 745. The spacer 747 may include, for example, an oxide such as silicon oxide or a nitride such as silicon nitride.

For example, each of the second contact plugs 745 may contact the lower surface of the selected gate electrode and may extend through the first gate electrodes 600 disposed thereunder (hereinafter referred to as non-selected gate electrode(s)) and may be electrically insulated from the non-selected gate electrode(s) by the spacer 747.

Since the first gate electrodes 600 included in the gate electrode structure have the same extension length in the second direction D2, each of the second contact plugs 745 may contact an upper surface of the corresponding first gate electrode 600, e.g., a portion other than an end portion in the second direction D2 of the selected gate electrode.

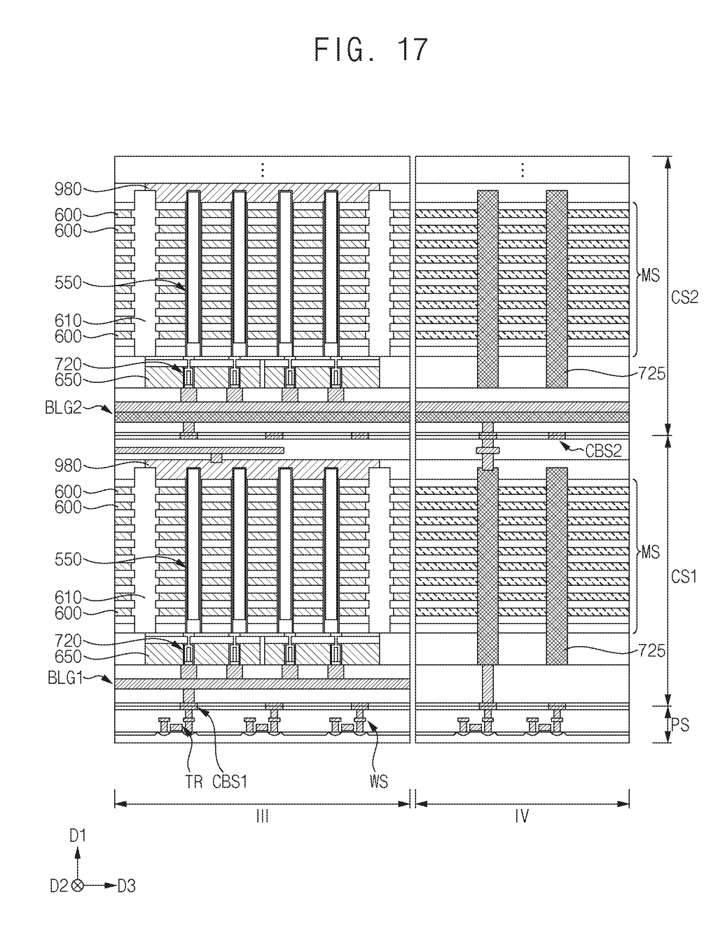

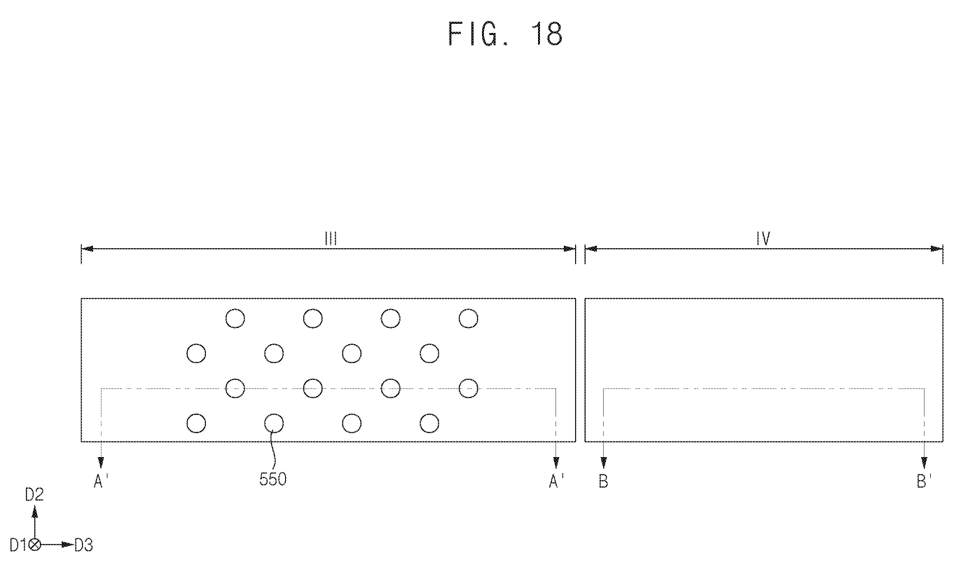

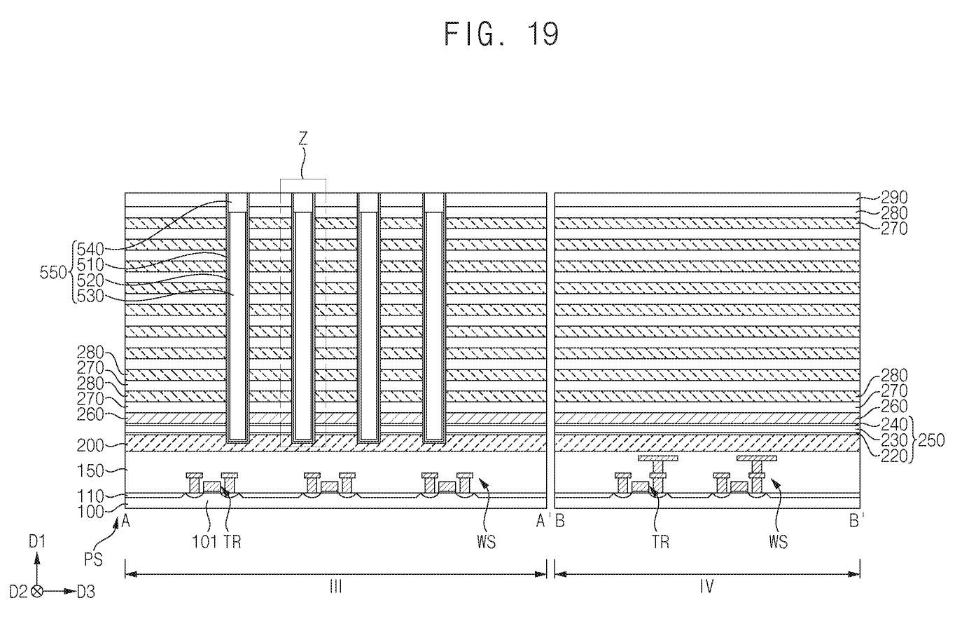

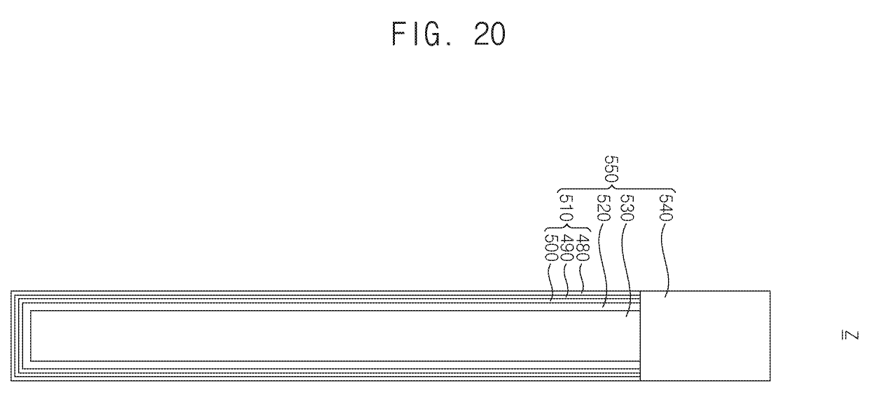

FIG. 17 is a cross-sectional view illustrating a semiconductor device in accordance with example embodiments. The semiconductor device is substantially the same as the semiconductor device described with reference to FIGS. 12-13, except for having a structure in which a plurality of cell structures CS1, CS2 …, and CSn are stacked on the peripheral circuit structure PS, and thus redundant description is omitted herein.

Referring to FIG. 17, the semiconductor device may include first, second …, and nth cell structures CS1, CS2 …, and CSn sequentially stacked on the peripheral circuit structure PS. Hereinafter, for convenience of explanation, only the first and second cell structures CS1 and CS2 are described.

The semiconductor device may include the peripheral circuit structure PS, a first cell bonding pattern structure CBS1, the first cell structure CS1, a second cell bonding pattern structure CBS2, and the second cell structure CS2 sequentially stacked in the first direction D1.

Each of the first and second cell structures CS1 and CS2 may be substantially the same as the cell structure CS of one of the semiconductor devices described with reference to FIGS. 12-16. In example embodiments, each of the first and second cell structures CS1 and CS2 may further include the mold structure MS and the through-via 725 described with reference to FIGS. 1-5.

The first cell structure CS1 may include a first bit line group BLG1 having bit lines spaced apart from each other in the second direction D2 and extending lengthwise in the third direction D3. The second cell structure CS2 may include a second bit line group BLG2 having bit lines spaced apart from each other in the second direction D2 and extending lengthwise in the third direction D3.

The bit line of the first bit line group BLG1 of the first cell structure CS1 may be electrically connected to the transistor TR of the peripheral circuit structure PS through the first cell bonding pattern structure CBS1.

In an example embodiment, the bit line of the first cell structure CS1 may have different thicknesses in the first direction D1 at the location of the first cell bonding pattern structure CBS1 to which the bit line is connected/contacting. For example, the bit line electrically connected to and/or contacting the first cell bonding pattern structure CBS1 disposed in the center of the first region I may have a structure substantially the same as the 1-2 bit line 775-2 of the semiconductor device described with reference to FIGS. 12-15, e.g., a single-layered structure. The bit line electrically connected to and/or contacting the first cell bonding pattern structure CBS1 disposed adjacent to each of the first and second edge portions (or edges) E1 and E2 of the first region I may have a structure substantially the same as the first and third bit line structures 797 and 799 of the semiconductor device described with reference to FIGS. 12-15, e.g., a double-layered structure.

In example embodiments, the bit lines of the first cell structure CS1 may have a layout substantially the same as the bit lines of the semiconductor device described with reference to FIGS. 12-15.

The bit line of the second bit line group BLG2 of the second cell structure CS2 may be electrically connected to the transistor TR of the peripheral circuit structure PS through the second cell bonding pattern structure CBS2 and the through-via 725 of the first cell structure CS1.

In an example embodiment, the bit line of the second cell structure CS2 may have difference thicknesses in the first direction D1 depending on the location of the through-via 725 of the first cell structure CS1 to which the bit line is connected. For example, the bit line electrically connected to the through-via 725 of the first cell structure CS1 disposed in the center of the first region I may have a structure substantially the same as the 1-2 bit line 775-2 of the semiconductor device described with reference to FIGS. 1-8, e.g., a single-layered structure. The second bit line BL2 electrically connected to the through-via 725 of the first cell structure CS1 disposed adjacent to each of the first and second edge portions E1 and E2 of the first region I may have a structure substantially the same as or similar to the first and third bit line structures 797 and 799 of the semiconductor device described with reference to FIGS. 1-8, e.g., a double-layered structure.

In example embodiments, the bit lines of the second cell structure CS2 may have a layout substantially the same as the bit lines of the semiconductor device described with reference to FIGS. 1-8.

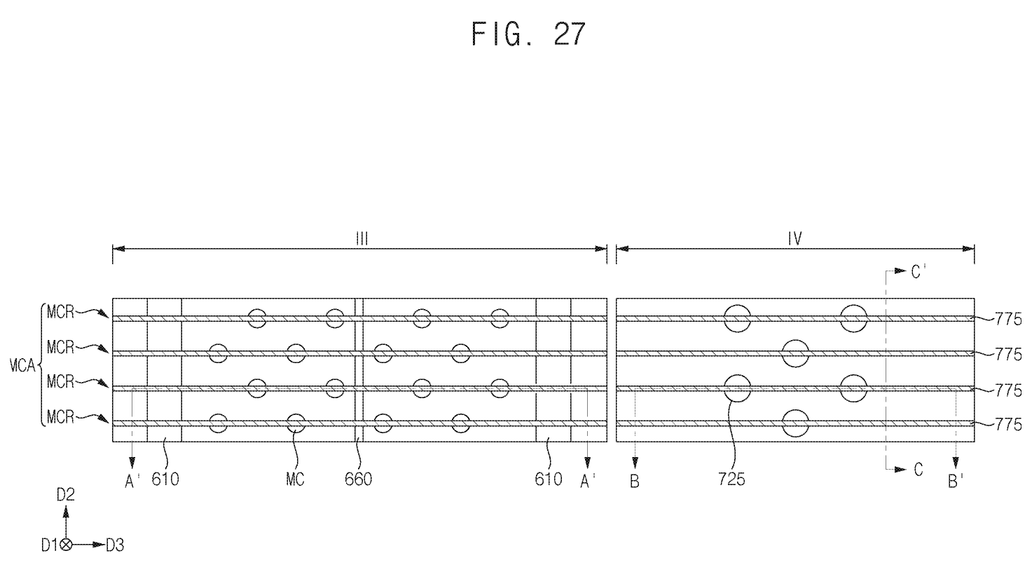

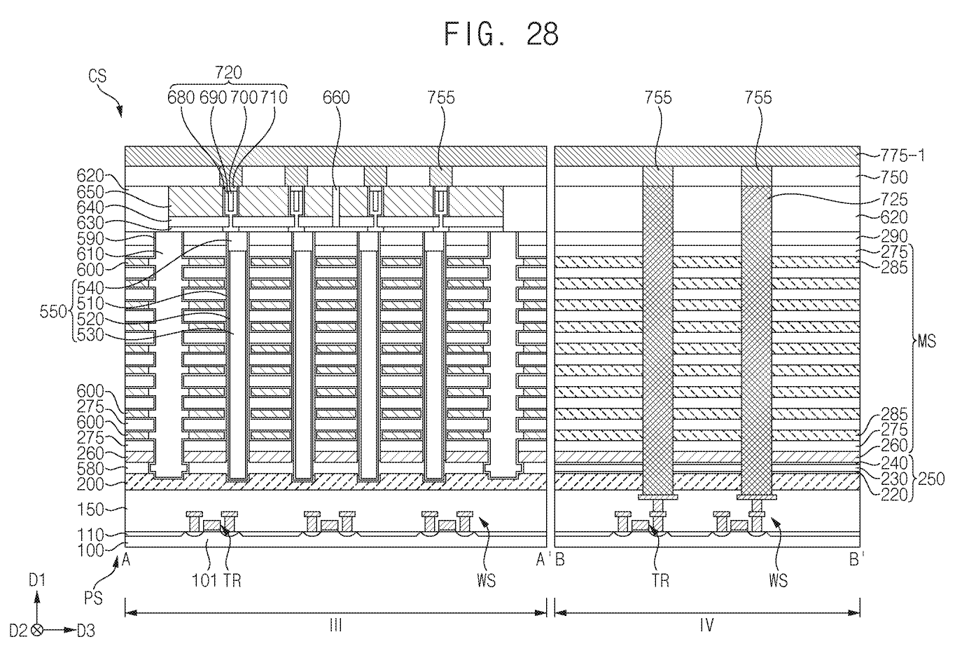

FIGS. 18 -29 are plan views and cross-sectional views illustrating a method of manufacturing a semiconductor device, for example, the semiconductor device of FIGS. 1-5 in accordance with example embodiments. Particularly, FIGS. 18, 21, 23, 25, and 27 are the plan views. Each of FIGS. 19, 22, 24, 26, and 28 includes cross-sectional views taken along a line A-A’ and a line B-B’, respectively, of a corresponding plan view. FIG. 20 is an enlarged cross-sectional view of a region Z of FIG. 19. FIG. 29 is a partial cross-sectional view taken along a line C-C’ of FIG. 27.

Referring to FIGS. 18-20, a peripheral circuit pattern and a first insulating interlayer 150 covering the peripheral circuit pattern may be formed on a first substrate 100.

The first substrate 100 may include a semiconductor material such as silicon, germanium, or silicon-germanium, or a group III-V compound such as GaP, GaAs, or GaSb. In an embodiment, the first substrate 100 may be a silicon-on-insulator (SOI) substrate or a germanium-on-insulator (GOI) substrate. The first substrate 100 may include first, second, third and fourth regions I, II, III and IV.

The peripheral circuit pattern may include a transistor TR and a wiring structure WS electrically connected to the transistor TR. Each component of the wiring structure WS may be formed by a patterning process or a damascene process.

A first CSP 200 and a sacrificial layer structure 250 may be formed on the first insulating interlayer 150. The sacrificial layer structure 250 may be partially removed to form a first opening exposing an upper surface of the first CSP 200, and a support layer 260 may be formed on an upper surface of the sacrificial layer structure 250 and on the exposed upper surface of the first CSP 200.

The sacrificial layer structure 250 may include first to third sacrificial layers 220, 230, and 240 sequentially stacked in the first direction D1. Each of the first and third sacrificial layers 220 and 240 may include, for example, an oxide such as silicon oxide, and the second sacrificial layer 230 may include, for example, a nitride such as silicon nitride.

The support layer 260 may be formed to have a uniform thickness, and accordingly, a first recess may be formed on a portion of the support layer 260 in the first opening (refer to FIG. 10). Hereinafter, a portion of the support layer 260 formed in the first opening and contacting the upper surface of the first CSP 200 is referred to as a support pattern 265.

A first insulating layer 270 and a fourth sacrificial layer 280 may be alternately and repeatedly stacked in the first direction D1 on the support layer 260 and the support pattern 265. Accordingly, a mold layer structure including the first insulating layers 270 and the fourth sacrificial layers 280 may be formed. The first insulating layer 270 may include, for example, an oxide such as silicon oxide, and the fourth sacrificial layer 280 may include a material having an etching selectivity with respect to the first insulating layer 270, for example, a nitride such as silicon nitride.

The second insulating interlayer 290 may be formed on an uppermost one of the first insulating layers 270. First channel holes may be formed through the second insulating interlayer 290, the mold layer structure, the support layer 260, the sacrificial layer structure 250, and an upper portion of the first CSP 200 on the third region III of the first substrate 100, and first memory channel structures 550 may be respectively formed in the first channel holes.

In example embodiments, each of the first memory channel structures 550 may include a first filling pattern 530 having a pillar shape extending lengthwise in the first direction D1, a first channel 520 covering a sidewall and a lower surface of the first filling pattern 530, a first charge storage structure 510 covering a sidewall and a lower surface of the first channel 520, and a first capping pattern 540 on upper surfaces of the first filling pattern 530, the first channel 520, and the first charge storage structure 510. The first charge storage structure 510 may include a first tunnel insulating pattern 500, a first charge storage pattern 490, and a first blocking pattern 480 sequentially stacked on the sidewall and the lower surface of the first channel 520.

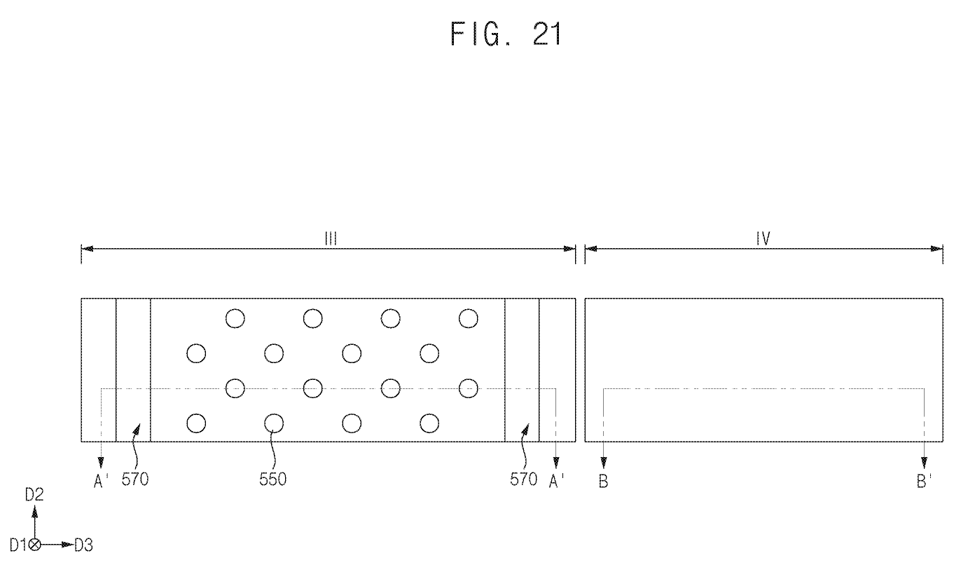

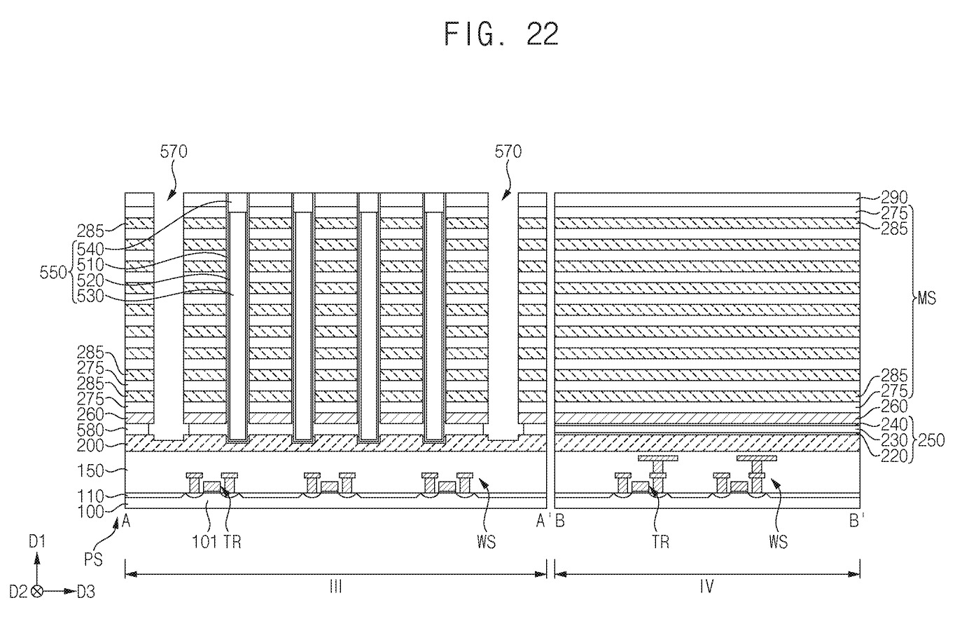

Referring to FIGS. 21 and 22, an etching process may be performed on the second insulating interlayer 290 and the mold layer structure on the second and third regions II and III of the first substrate 100 to form a second opening 570 exposing an upper surface of the support layer 260 or the support pattern 265 (shown in FIG. 10) and extending in the second direction D2.

In example embodiments, on the second and third regions II and III of the first substrate 100, the second opening 570 may extend in the second direction D2, and a plurality of second openings 570 may be formed to be spaced apart from each other in the third direction D3. Accordingly, the mold layer structure may be divided into a plurality of mold structures MS spaced apart from each other in the third direction D3 by the first openings 570, and the first insulating layers 270 and the fourth sacrificial layers 280 included in the mold layer structure may be divided into first insulating patterns 275 and fourth sacrificial patterns 285, respectively, extending in the second direction D2.

Although the mold structures MS extend in the second direction D2 and are spaced apart from each other in the third direction D3 by the etching process for forming the second opening 570, the mold structures MS may not collapse due to the first memory channel structures 550 penetrating the mold structures MS.

A spacer layer (not shown) may be formed on a sidewall of the second opening 570, the exposed upper surface (not shown) of the support layer 260 or the support pattern 265, and an upper surface of the second insulating interlayer 290, and an anisotropic etching process may be performed on the spacer layer. Accordingly, a portion of the spacer layer on the upper surface of the support layer 260 or the support pattern 265 and the upper surface of the second insulating interlayer 290 may be removed to form a spacer.

The spacer layer may include, for example, polysilicon.

Portions of the support layer 260 and the support pattern 265, which are not covered by the spacers and are exposed, and a portion of the sacrificial layer structure 250 thereunder may be removed so that the second opening 570 may be enlarged downward. Accordingly, the second opening 570 may expose the upper surface of the first CSP 200 and may further extend through an upper portion of the first CSP 200.

When the sacrificial layer structure 250 is partially removed, the sidewall of the second opening 570 may be covered by the spacer, and since the spacer may include a material different from the sacrificial layer structure 250, the first insulating patterns 275 and the fourth sacrificial patterns 285 included in the mold structure MS may not be removed.

A wet etching process may be performed through the second opening 570, and accordingly, the sacrificial layer structure 250 exposed by the second opening 570 may be removed, thereby forming a first gap between the first CSP 200 and the support layer 260 on the third region III of the first substrate 100. The wet etching process may be performed using an etchant such as hydrofluoric acid (HF) and/or phosphoric acid (H₃PO₄).

In example embodiments, the etchant may not reach a portion of the sacrificial layer structure 250 on the second and fourth regions II and IV of the first substrate 100 due to the support layer 260, and accordingly, the portion of the sacrificial layer structure 250 on the second and fourth regions II and IV may not be removed but remain.

As the first gap is formed, a portion of a sidewall of the first charge storage structure 510 may be exposed (not shown), and the exposed sidewall of the first charge storage structure 510 may be removed during the wet etching process, thereby exposing an outer sidewall of the first channel 520. Accordingly, the first charge storage structure 510 may be separated into an upper portion penetrating the mold structure MS to cover most (e.g., more than half) of the outer sidewall of the first channels 520 and a lower portion covering a bottom of the first channel 510 and formed on the upper portion of the first CSP 200 as shown in FIG. 22.

The spacer may be removed, and a channel connection layer (not shown) may be formed on the sidewall of the second opening 570 and in the first gap. For example, an etch-back process may be performed to remove a portions of the channel connection layer in the second opening 570, thereby forming a channel connection pattern 580 in the first gap.

As the channel connection pattern 580 is formed, neighboring ones of the first channels 520 between the second openings 570 within a memory block region may be connected to each other.

In an embodiment, an air gap may be formed in the channel connection pattern 580.

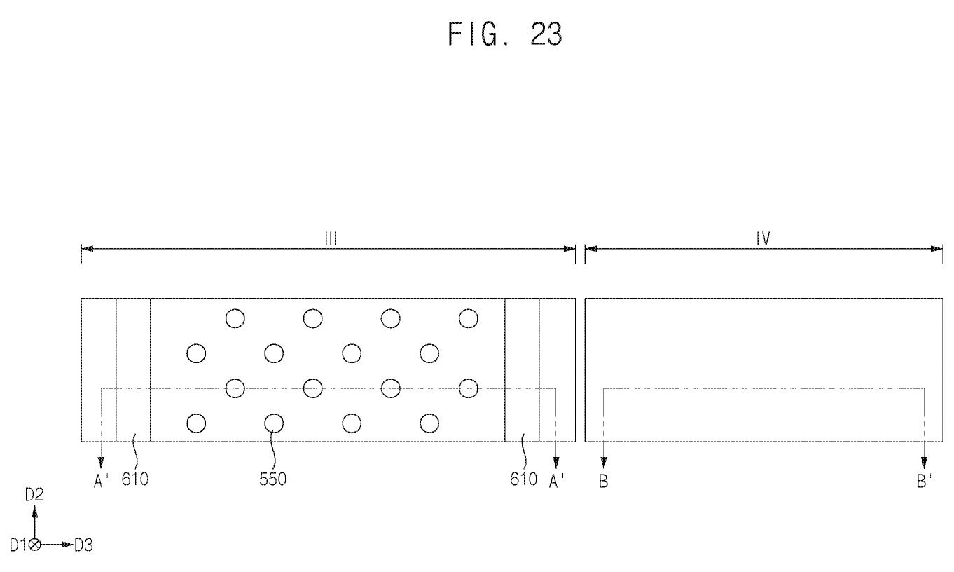

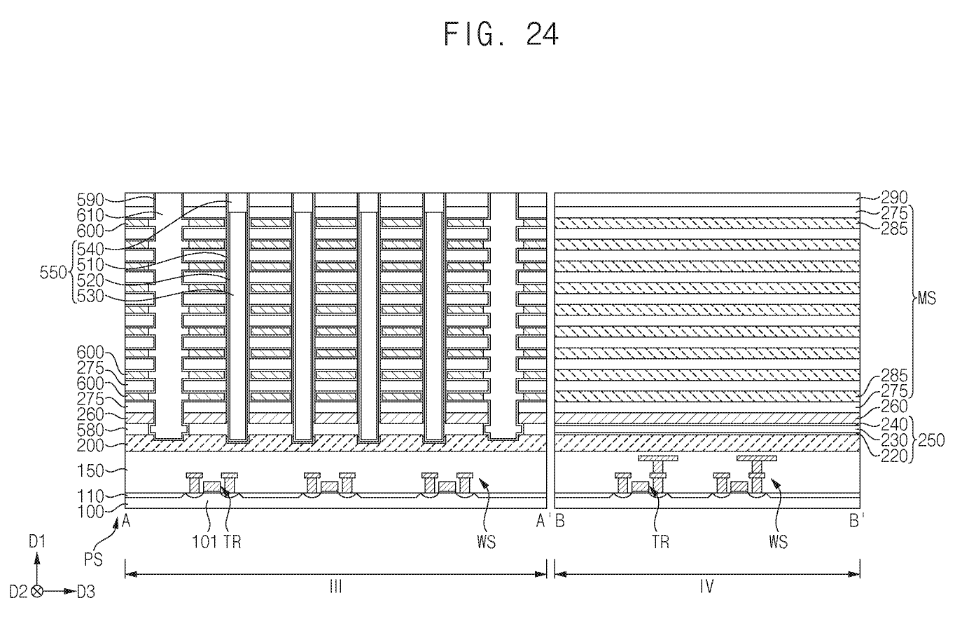

Referring to FIGS. 23 and 24, the fourth sacrificial patterns 285 exposed by the second opening 570 may be removed to form second gaps between the first insulating patterns 275 neighboring in the first direction D1, and a portion of the outer sidewall of the first charge storage structure 510 included in the first memory channel structure 550 may be exposed by each of the second gaps.

According to an example embodiment, the fourth sacrificial patterns 285 may be removed through a wet etching process using an etchant including phosphoric acid (H₃PO₄) or sulfuric acid (H₂SO₄).

The wet etching process may be performed through the second openings 570, and portions of the fourth sacrificial patterns 285 between the second openings 570 may be removed by the etchant respectively introduced in horizontal directions through the second openings 570 on the second and third regions II and III of the first substrate 100.

In an embodiment, the etchant may not reach portions of the fourth sacrificial patterns 285 on the fourth region IV of the first substrate 100, and accordingly, the portions of the fourth sacrificial patterns 285 on the fourth region IV of the first substrate 100 may not be removed but remain. For example, the mold structure MS may remain on the fourth region IV of the first substrate 100.

A second blocking layer may be formed on the outer sidewall of the first charge storage structure 510 exposed by the second gap, an inner wall of the second gap, a surface of the first insulating pattern 275, a sidewall of the second insulating interlayer 290, and an upper surface of the second insulating interlayer 290, and a first gate electrode layer may be formed on the second blocking layer.

The first gate electrode layer may be partially removed to form a first gate electrode 600 in each of the second gaps. According to an example embodiment, the first gate electrode layer may be partially removed through a wet etching process.

In example embodiments, the first gate electrode 600 may extend, e.g., .lengthwise, in the second direction D2, and a plurality of first gate electrodes 600 may be formed to be spaced apart from each other in the first direction D1 to form a first gate electrode structure. In example embodiments, a plurality of first gate electrode structures may be spaced apart from each other in the third direction D3 by the first openings 570.

A first separation layer filling each of the second openings 570 may be formed on the second blocking layer, and may be planarized until the upper surface of the second insulating interlayer 290 is exposed.

Accordingly, the second blocking layer may be divided into a plurality of second blocking patterns 590, and the first separation layer may be divided into a plurality of first separation patterns 610.

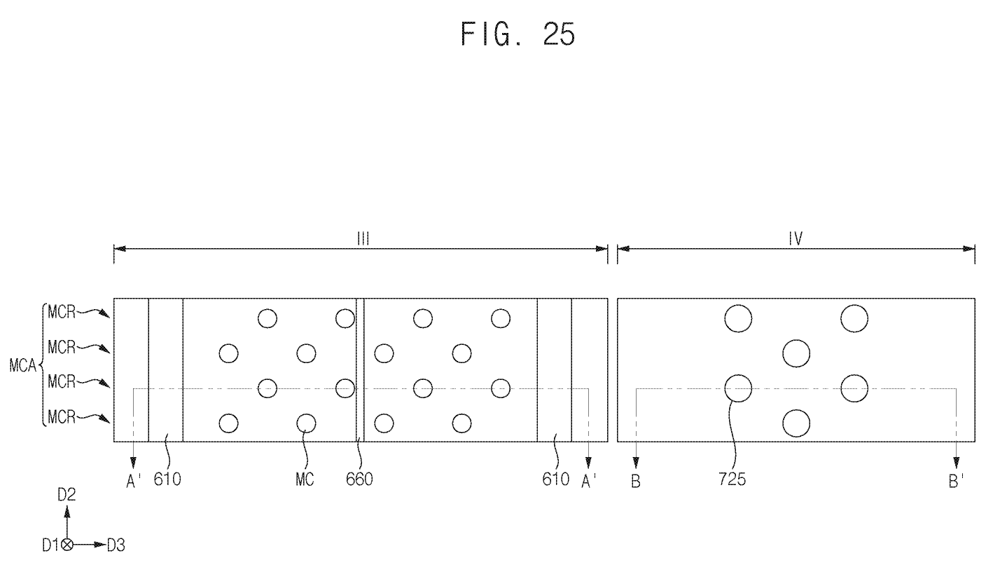

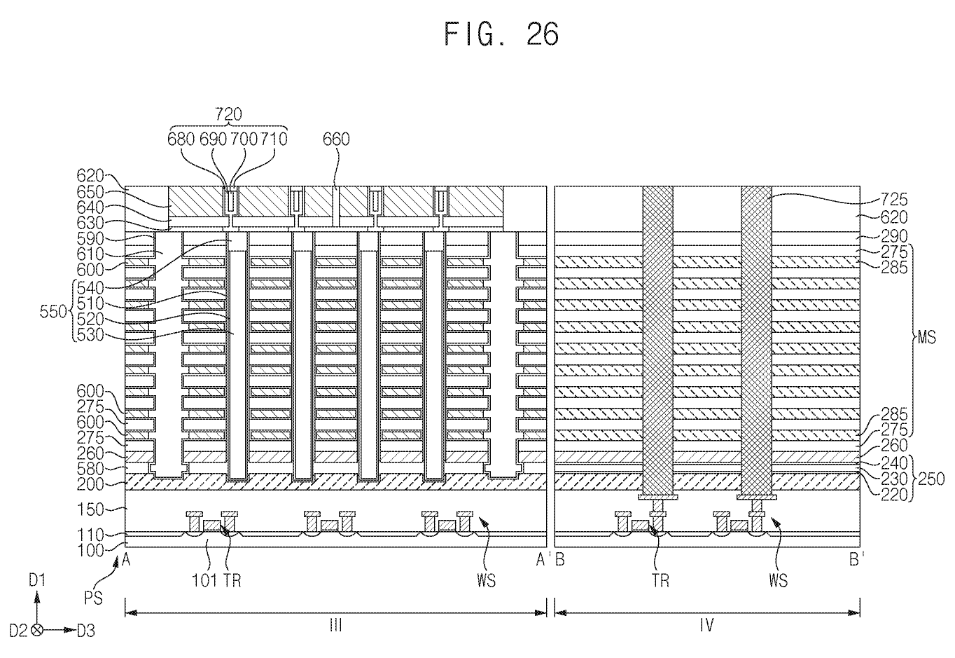

Referring to FIGS. 25 and 26, a third insulating interlayer 620 may be formed on the upper surface of the second insulating interlayer 290.

A third opening exposing the upper surface of the second insulating interlayer 290 may be formed by partially removing the third insulating interlayer 620 on the third region III of the first substrate 100, and a fourth insulating interlayer 630, an etch stop layer 640, and a second gate electrode layer may be sequentially stacked on the exposed upper surface of the second insulating interlayer 290 to fill the third opening.

The fourth insulating interlayer 630 may include an insulating nitride such as silicon nitride, the etch stop layer 640 may include an oxide such as silicon oxide, and the second gate electrode layer may include polysilicon doped with impurities.

A fourth opening may be formed through the second gate electrode layer and the etch stop layer 640 to expose an upper surface of the fourth insulating interlayer 630, and a second separation pattern 660 may be formed in the fourth opening. In example embodiments, the second separation pattern 660 may extend, e.g., lengthwise, in the second direction D2, and a plurality of second separation patterns 660 may be formed to be spaced apart from each other in the third direction D3. Each of the second separation patterns 660 may be formed between the first separation patterns 610 adjacent to each other in the third direction D3, e.g., in a plan view.

As the second separation patterns 660 are formed, the second gate electrode layer may be separated into second gate electrodes 650 each extending, e.g., lengthwise, in the second direction D2. The second gate electrode 650 together with the first gate electrode structure including the first gate electrodes 600 thereunder may form a gate electrode structure.

A second channel hole may be formed through the second gate electrodes 650 to expose an upper surface of the etch stop layer 640. The second channel hole may partially overlap the first memory channel structure 550 in the first direction D1. In example embodiments, a plurality of second channel holes may be formed in each of the second and third directions D2 and D3.

A second charge storage structure layer may be formed on a sidewall and a bottom of the second channel hole and on the second gate electrodes 650, the first and second separation patterns 610 and 660, and the third insulating interlayer 620, and an etch-back process may be performed on the second charge storage structure layer to form a second charge storage structure 680 on a sidewall and an edge portion of the bottom of the second channel hole. The second charge storage structure 680 may include a third blocking pattern, a second charge storage pattern, and a second tunnel insulating pattern sequentially stacked from the sidewall of the second channel hole.

A portion of the etch stop layer 640 exposed by the second charge storage structure 680 and a portion of the fourth insulating interlayer 630 thereunder may be removed to enlarge/extend the second channel hole in the first direction D1, and a portion of the fourth insulating interlayer 630 adjacent to the enlarged second channel hole may be additionally removed to enlarge/extend the second channel hole in the horizontal direction, e.g., as shown in FIG. 26. Accordingly, the second channel hole may expose at least a portion of an upper surface of the first memory channel structure 550. The second channel hole may also expose an upper surface of a portion of the second insulating interlayer 290 adjacent to the first memory channel structure 550.

A second channel 690, a second filling pattern 700, and a second capping pattern 710 may be formed in each of the second channel holes.

In example embodiments, the second channel 690 may include a lower portion surrounded by and horizontally overlapping the fourth insulating interlayer 630, a central portion surrounded by and horizontally overlapping the etch stop layer 640, and an upper portion surrounded by and horizontally overlapping the second charge storage structure 680. The second filling pattern 700 may have a lower surface and a sidewall covered by the upper portion of the second channel 690, and the second capping pattern 710 may be formed on the second channel 690 and the second filling pattern 700 and may be surrounded by the second charge storage structure 680.

The second charge storage structure 680, the second channel 690, the second filling pattern 700, and the second capping pattern 710 may collectively form a second memory channel structure 720, which may contact and be connected to the upper surface of the first memory channel structure 550.

The first and second memory channel structures 550 and 720 may collectively form a memory channel structure MS.

A through-via 725 extending through the third insulating interlayer 620, the mold structure MS, the sacrificial layer structure 250, the first CSP 200, and an upper portion of the first insulating interlayer 150 may be formed on the fourth region IV of the first substrate 100. The through-via 725 may be electrically connected to the transistor TR of the peripheral circuit pattern through the wiring structure WS.

Referring to FIGS. 27-29, a fifth insulating interlayer 750 may be formed on the second gate electrode 650, the second separation pattern 660, the memory channel structure MS, and the third insulating interlayer 620, and a first via 755 extending through the fifth insulating interlayer 750 and contacting an upper surface of the memory channel structure MS may be formed.

A sixth insulating interlayer 770 may be formed on the fifth insulating interlayer 750 and the first via 755, and a first bit line 775 extending through the sixth insulating interlayer 770 and contacting an upper surface of the first via 755 may be formed.

In example embodiments, the first bit line 775 may extend lengthwise in the third direction D3 on the third and fourth regions III and IV of the first substrate 100, and a plurality of first bit lines 775 may be spaced apart from each other in the second direction D2. In example embodiments, widths of the first bit lines 775 in the second direction D2 may be substantially the same.

In example embodiments, the first bit lines 775 may include a 1-1 bit line 775-1, a 1-2 bit line 775-2, and a 1-3 bit line 775-3. In example embodiments, the 1-1 bit line 775-1 may be electrically connected to the transistor TR of the peripheral circuit structure PS through the through-via 725 disposed on the 4-1 region IV-1 of the first substrate 100. The 1-2 bit line 775-2 may be electrically connected to the transistor TR of the peripheral circuit structure PS through the through-via 725 disposed on the 4-2 region IV-2 of the first substrate 100. The 1-3 bit line 775-3 may be electrically connected to the transistor TR of the peripheral circuit structure PS through the through-via 725 disposed on the 4-3 region IV-3 of the first substrate 100.

Referring back to FIGS. 1-5, a seventh insulating interlayer 790 may be formed on the sixth insulating interlayer 770 and the first bit line 775.

A second bit line 795 may be formed through the seventh insulating interlayer 790 to extend lengthwise in the third direction D3 on the third and fourth regions III and IV of the first substrate 100, and a plurality of second bit lines 795 may be spaced apart from each other in the second direction D2. Each of the second bit lines 795 may contact an upper surface of a corresponding 1-1 bit line 775-1 or a corresponding 1-3 bit line 775-3, and may extend lengthwise in the third direction D3. For example, the second bit lines 795 may be formed on the 1-1 and 1-3 bit lines 775-1 and 775-3, which are electrically connected to the peripheral circuit structure PS through the through-vias 725 disposed on the 4-1 and 4-3 regions IV-1 and IV-3 of the first substrate 100 at opposite ends in the second direction D2.

By performing the processes described above, the manufacturing of the semiconductor device may be completed.

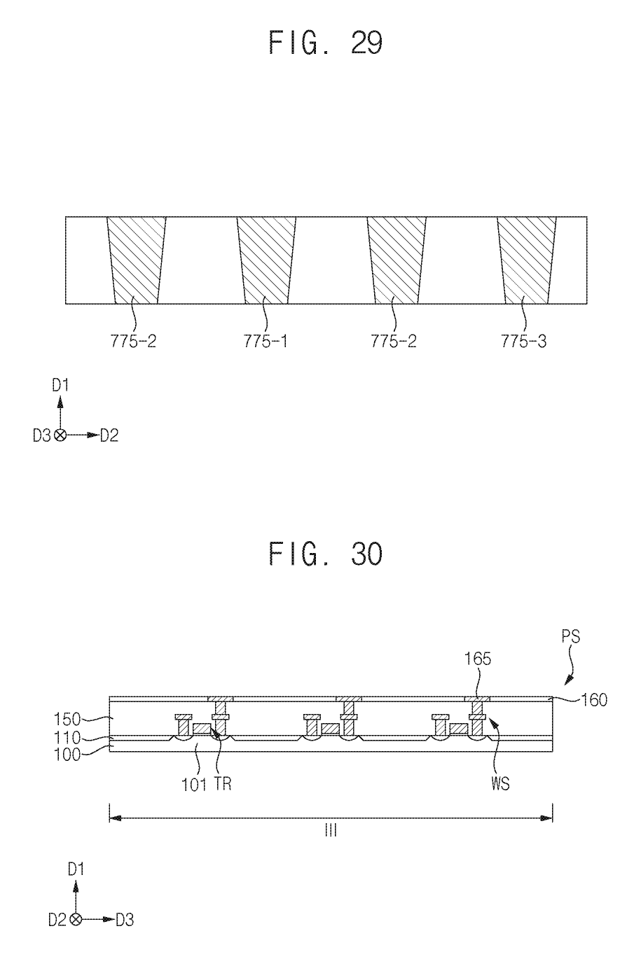

FIGS. 30-32 are cross-sectional views illustrating a method of manufacturing the semiconductor device of FIG. 12 and 13 in accordance with example embodiments. This method may include processes that are substantially the same as the processes described with reference to FIGS. 18-29 and 1-5, and thus redundant description is omitted herein.

Referring to FIG. 30, a first bonding layer 160 including a first bonding pattern 165 electrically connected to the wiring structure WS may be formed on the peripheral circuit structure PS.

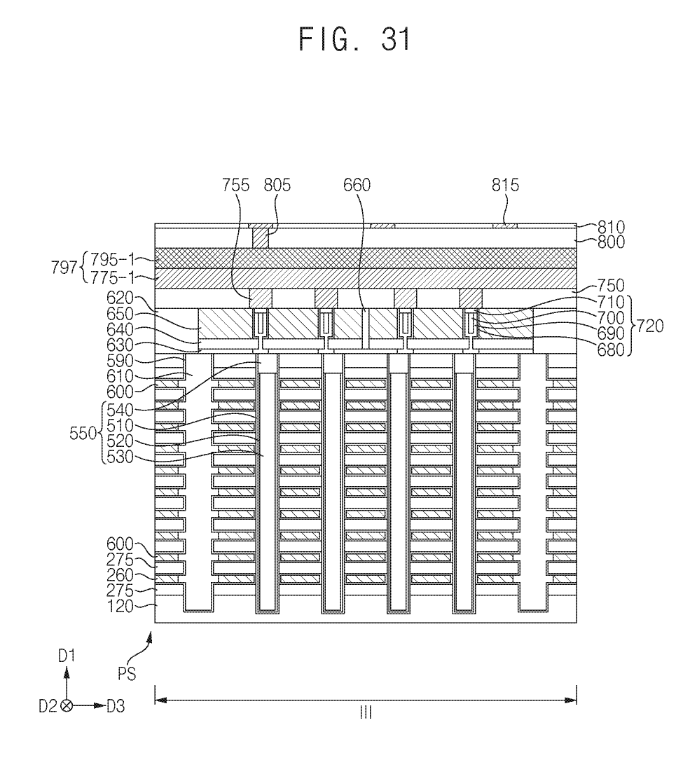

Referring to FIG. 31, by performing processes that are substantially the same as or similar to the processes described with reference to FIGS. 18-29 and 1-5, a cell structure CS including the gate electrode structure, the first insulating pattern 275, the memory channel structure MC, the first and second separation patterns 610 and 660, and the bit line may be formed on the second substrate 120. Unlike the processes described with reference to FIGS. 18-29 and 1-5, the processes of forming the sacrificial layer structure 250, the support layer 260, the support pattern 265, and the channel connection pattern 580 may not be performed in the present embodiment.

An eighth insulating interlayer 800 may be formed on the bit line, and a second via 805 extending through the eighth insulating interlayer 800 in the first direction D1 and contacting the upper surface of the bit line may be formed.

A second bonding layer 810 including a second bonding pattern 815 contacting an upper surface of the second via 805 may be formed on the eighth insulating interlayer 800.

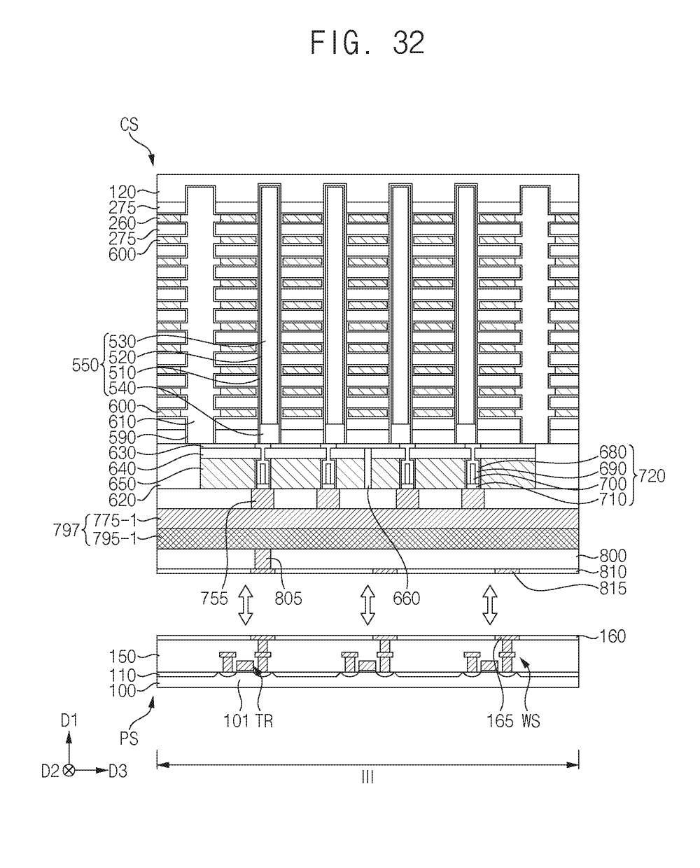

Referring to FIG. 32, after flipping the cell structure CS, the cell structure CS and the peripheral circuit structure PS may be bonded to each other such that the second bonding layer 810 contacts the first bonding layer 160. The first and second bonding patterns 815 and 165 may contact each other, and the first and second bonding patterns 815 and 165 may collectively form a bonding pattern structure BS.

Referring back to FIGS. 12 and 13, the second substrate 120 may be removed, for example, through a grinding process, thereby exposing an upper portion of the first charge storage structure 510 and an upper surface of a topmost one of the first insulating patterns 275. The exposed upper portion of the first charge storage structure 510 may be removed, thereby exposing an outer sidewall and an upper surface of an upper portion of the first channel 520.

A second CSP layer may be formed on the outer sidewall and the upper surface of the upper portion of the first channel 520, and on the upper surface of the topmost one of the first insulating patterns 275, and the second CSP layer may be patterned to form a second CSP 980. A ninth insulating interlayer 990 covering the second CSP 980 may be formed, and a planarization process may be performed on an upper portion of the ninth insulating interlayer 990 until an upper surface of the second CSP 980 is exposed.

By performing the processes described above, the manufacturing of the semiconductor device may be completed.

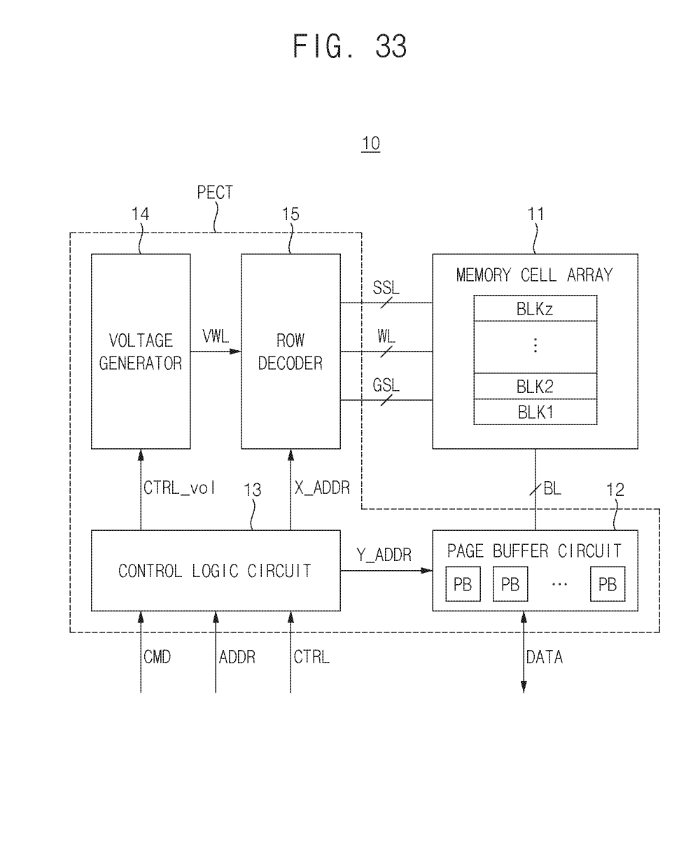

FIG. 33 is a block diagram illustrating a semiconductor device in accordance with example embodiments.

Referring to FIG. 33, a semiconductor device 10 may include a memory cell array 11 and a peripheral circuit PECT, and the peripheral circuit PECT may include a page buffer circuit 12, a control logic circuit 13, a voltage generator 14, and a row decoder 15. Although not shown in FIG. 33, the peripheral circuit PECT may further include a data input/output circuit or an input/output interface. In addition, the peripheral circuit PECT may further include a temperature sensor, a command decoder, an address decoder, etc.

The memory cell array 11 may include a plurality of memory blocks BLK1 to BLKz (z is a positive integer), and each of the plurality of memory blocks BLK1 to BLKz may include a plurality of memory cells. The memory cell array 11 may be electrically connected to the page buffer circuit 12 through bit lines BL, and may be electrically connected to the row decoder 15 through word lines WL, string select lines SSL, and ground select lines GSL. For example, the memory cells may be flash memory cells.

The page buffer circuit 12 may include a plurality of page buffers PB. Each of the plurality of page buffers PB may be electrically connected to memory cells of the memory cell array 11 through a corresponding bit line. The page buffer circuit 12 may select at least one of the bit lines BL under control of the control logic circuit 13. For example, the page buffer circuit 12 may select some of the bit lines BL in response to a column address Y_ADDR received from the control logic circuit 13. Each of the plurality of page buffers PB may operate as a write driver or a sense amplifier. For example, in a program operation, each of the plurality of page buffers PB may apply a voltage corresponding to program data DATA to a bit line to store the data DATA in a memory cell. For example, in a program verify operation or a read operation, each of the plurality of page buffers PB may sense current or voltage through a bit line to detect the programmed data DATA.

The control logic circuit 13 may output various control signals for programming data into the memory cell array 11, reading data from the memory cell array 11, or erasing data stored in the memory cell array 11, based on a command CMD, an address ADDR, and a control signal CTRL. Such control signals may include, for example, a voltage control signal CTRL_vol, a row address X_ADDR, and a column address Y_ADDR. Thus, the control logic circuit 13 may generally control various operations in the semiconductor device 10. For example, the control logic circuit 13 may receive the command CMD, the address ADDR, and the control signal CTRL from a memory controller.

The voltage generator 14 may generate various types of voltages for performing program, read, and erase operations on the memory cell array 11 based on the voltage control signal CTRL_vol. Specifically, the voltage generator 14 may generate a word line voltage VWL, e.g., a program voltage, a read voltage, a pass voltage, an erase verify voltage, or a program verify voltage. In addition, the voltage generator 14 may further generate a string select line voltage and a ground select line voltage based on the voltage control signal CTRL_vol.

The row decoder 15 may select one of the plurality of memory blocks BLK1 to BLKz in response to the row address X_ADDR received from the control logic circuit 13, may select one of the word lines WL of the selected memory block, and may select one of the string select lines SSL. For example, during a program operation, the row decoder 15 may apply the program voltage and the program verify voltage to the selected word line, and during a read operation, the row decoder 15 may apply the read voltage to the selected word line.

Even though different figures illustrate variations of example embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been shown and described with reference to example embodiments thereof, it will be apparent to those of ordinary skill in the art that various modifications in form and details may be made thereto without departing from the spirit and scope of the inventive concept.

What is claimed is:

1. A semiconductor device, comprising:
a substrate including a first region having second regions and third regions that are alternately and repeatedly arranged in a first direction;
a peripheral circuit pattern on the substrate;
a gate electrode structure on each of the second regions of the substrate;
memory channel structures each extending through the gate electrode structure;
a first bit line and a second bit line on the gate electrode structure on the first region of the substrate, each of the first bit line and the second bit line extending in the first direction, and the first bit line and the second bit line being spaced apart from each other in a second direction crossing the first direction;
a third bit line extending in the first direction on the first bit line; and
through-vias on the third regions of the substrate,
wherein the third regions include a third primary region and a third secondary region,
wherein the third primary region is closer to a first edge of the first region than the third secondary region in the first direction,
wherein the first bit line is electrically connected to the peripheral circuit pattern through a first through-via disposed on the third primary region of the substrate among the through-vias, and the second bit line is electrically connected to the peripheral circuit pattern through a second through-via disposed on the third secondary region of the substrate among the through-vias.

2. The semiconductor device of claim 1, wherein an upper surface of the first bit line has a first width in the second direction, an upper surface of the third bit line has a second width in the second direction, and the second width is greater than the first width.

3. The semiconductor device of claim 2, wherein a lower surface of the third bit line has a third width in the second direction, and the third width is less than the first width.

4. The semiconductor device of claim 1, further comprising:
a fourth bit line extending in the first direction, the fourth bit line being spaced apart from the second bit line in the second direction; and
a fifth bit line extending in the first direction on the fourth bit line, the fifth bit line being spaced apart from the third bit line in the second direction,
wherein the third regions include a third tertiary region,
wherein the third tertiary region is closer to a second edge of the first region than the third secondary region in the first direction, and
wherein the fourth bit line is electrically connected to a third through-via disposed on the third tertiary region of the substrate among the through-vias.

5. The semiconductor device of claim 4, wherein the first bit line and the third bit line collectively form a first bit line structure, and the fourth bit line and the fifth bit line collectively form a second bit line structure, and
wherein a basic unit formed of the first and second bit line structures and two second bit lines sequentially arranged in an order of one second bit line, the first bit line structure, the other second bit line, and the second bit line structure in the second direction is periodically disposed in the second direction on the first region of the substrate.

6. The semiconductor device of claim 4, wherein the first bit line and the third bit line collectively form a first bit line structure, and the fourth bit line and the fifth bit line collectively form a second bit line structure,
wherein a basic unit formed of the first bit line structure, the second bit line, and the second bit line structure sequentially arranged in the second direction is periodically disposed in the second direction on the first region of the substrate.

7. The semiconductor device of claim 6, wherein a first distance between an upper surface of the first bit line and an upper surface of the second bit line in the second direction is less than a second distance between an upper surface of the first bit line and an upper surface of the fourth bit line in the second direction.

8. The semiconductor device of claim 1, further comprising:
a mold structure on the third regions of the substrate,
wherein each of the through-vias extends through the mold structure.

9. The semiconductor device of claim 1,
wherein the gate electrode structure is disposed on the third regions of the substrate, and each of the through-vias extends through the gate electrode structure and is insulated from the gate electrode structure, and
wherein each of the through-vias is electrically insulated from the gate electrode structure by an insulating pattern.

10. The semiconductor device of claim 1, further comprising:
a channel connection pattern between the peripheral circuit pattern and the gate electrode structure, the channel connection pattern electrically connecting the memory channel structures to each other.

11. A semiconductor device, comprising:
a peripheral circuit pattern on a substrate, the substrate including a first region;
bonding pattern structures on the peripheral circuit pattern;
a first bit line structure on the bonding pattern structures, the first bit line structure including a first bit line extending in a first direction parallel to an upper surface of the substrate and a second bit line contacting an upper surface of the first bit line, the second bit line extending in the first direction on the upper surface of the first bit line;
a third bit line extending in the first direction, the third bit line spaced apart from the second bit line in a second direction parallel to the upper surface of the substrate and crossing the first direction;
a gate electrode structure on the first bit line structure and the third bit line; and
memory channel structures each extending through the gate electrode structure on the first region of the substrate,
wherein the bonding pattern structures include a first bonding pattern structure closer to a first edge of the first region than a second bonding pattern structure in the first direction, and
wherein the first bit line structure is electrically connected to the peripheral circuit pattern through the first bonding pattern structure, and the third bit line is electrically connected to the peripheral circuit pattern through the second bonding pattern structure.

12. The semiconductor device of claim 11, wherein a lower surface of the second bit line has a first width in the second direction, a lower surface of the first bit line has a second width in the second direction, and the second width is greater than the first width.

13. The semiconductor device of claim 11, further comprising:
a second bit line structure including a fourth bit line spaced apart from the first bit line in the second direction and a fifth bit line contacting an upper surface of the fourth bit line, the fifth bit line extending in the first direction on the upper surface of the fourth bit line, the fourth bit line being spaced apart from the third bit line in the second direction,
wherein the bonding pattern structures further include a third bonding pattern structure closer to a second edge of the first region than the second bonding pattern structure in the first direction, and
wherein the second bit line structure is electrically connected to the peripheral circuit pattern through the third bonding pattern structure.

14. The semiconductor device of claim 13, wherein a basic unit formed of the first and second bit line structures and two third bit lines sequentially arranged in an order of one third bit line, the first bit line structure, the other third bit line, and the second bit line structure in the second direction is periodically disposed in the second direction on the first region of the substrate.

15. The semiconductor device of claim 13, wherein a basic unit formed of the first bit line structure, the third bit line, and the second bit line structure sequentially arranged in the second direction is periodically disposed in the second direction on the first region of the substrate.

16. The semiconductor device of claim 11, further comprising:
a common source plate (CSP) disposed on the gate electrode structure, the CSP electrically connecting the memory channel structures to each other.

17. A semiconductor device comprising:
a substrate including a first region having second regions and third regions that are alternately and repeatedly arranged in a first direction;
a peripheral circuit pattern on the substrate; and
a first bonding pattern structure, a first cell structure, a second bonding pattern structure, and a second cell structure sequentially stacked in a vertical direction on the peripheral circuit pattern,
wherein the first cell structure includes:
a first bit line group on the first bonding pattern structure;
a first gate electrode structure on the first bit line group on the second regions of the substrate;
first memory channel structures each extending through the first gate electrode structure; and
through-vias on the third regions of the substrate,
wherein the second cell structure includes:
a second bit line group on the second bonding pattern structure;
a second gate electrode structure on the second bit line group on the second regions of the substrate; and
second memory channel structures each extending through the second gate electrode structure,
wherein the second bit line group includes:
a first bit line structure on the second bonding pattern structure, the first bit line structure including a first bit line extending in the first direction and a second bit line extending on an upper surface of the first bit line in the first direction; and
a third bit line extending in the first direction, the third bit line being spaced apart from the second bit line in a second direction parallel to the upper surface of the substrate and crossing the first direction,
wherein the third regions include a third primary region and a third secondary region,
wherein the third primary region is closer to a first edge of the first region than the third secondary region in the first direction, and
wherein the first bit line structure is electrically connected to the peripheral circuit pattern through a first through-via disposed on the third primary region of the substrate among the through-vias, and the third bit line is electrically connected to the peripheral circuit pattern through a second through-via disposed on the third secondary region of the substrate among the through-vias.

18. The semiconductor device of claim 17, wherein a lower surface of the second bit line has a first width in the second direction, a lower surface of the first bit line has a second width in the second direction, and the second width is greater than the first width.

19. The semiconductor device of claim 17, wherein the first bit line group includes:
a second bit line structure on the first bonding pattern structure, the second bit line structure including a fourth bit line extending in the first direction and a fifth bit line extending on an upper surface of the third bit line in the first direction; and
a sixth bit line extending in the first direction, and being spaced apart from the fifth bit line in the second direction,
wherein the semiconductor device includes a plurality of first bonding pattern structures including the first bonding pattern structure, the plurality of first bonding pattern structures including a first primary bonding pattern structure and a first secondary bonding pattern structure,
wherein the first primary bonding pattern structure is closer to the first edge of the first region of the substrate than the first secondary bonding pattern structure in the first direction, and
wherein the second bit line structure is electrically connected to the peripheral circuit pattern through the first primary bonding pattern structure, and the sixth bit line is electrically connected to the peripheral circuit pattern through the first secondary bonding pattern structure.

20. The semiconductor device of claim 17, further comprising:
a first common source plate (CSP) disposed on the first gate electrode structure and connecting the first memory channel structures to each other; and
a second CSP disposed on the second gate electrode structure and connecting the second memory channel structures to each other.
